(19) United States
(12) Patent Application Publication
(10) Pub. No.: US 2025/0370014 A1
(43) Pub. Date: Dec. 4, 2025

(54) SENSING CIRCUIT WITH HARMONICS FILTERING

(71) Applicant: TEXAS INSTRUMENTS INCORPORATED, Dallas, TX (US)

(72) Inventors: Bassem IBRAHIM, Allen, TX (US); David P. MAGEE, Allen, TX (US)

(21) Appl. No.: 18/677,305

(22) Filed: May 29, 2024

(51) Int. Cl. G01R 19/25

(52) U.S. Cl. CPC G01R 19/2506

(57) ABSTRACT

An apparatus includes: a driver circuit having a driver output, the driver circuit including a pulse width modulation (PWM) circuit configured to provide a PWM signal at the driver output at a frequency; a sensing circuit having a sense input and a sense output; and a processing circuit having a processing input and a processing output, the processing input coupled to the sense output, the processing circuit including a filter having zeros at the frequency and multiples of the frequency.

### BACKGROUND

Some sense operations involve providing a signal to a circuit to enable the sense operations. The signal may introduce harmonics that affect the signal-to-noise ratio (SNR) of the sense operations. Because of the harmonics, the SNR is reduced, which can reduce the accuracy of the sensing operations and other related control operations.

### SUMMARY

In an example, an apparatus includes: a driver circuit having a driver output, the driver circuit including a pulse width modulation (PWM) circuit configured to provide a PWM signal at the driver output at a frequency; a sensing circuit having a sense input and a sense output; and a processing circuit having a processing input and a processing output, the processing input coupled to the sense output, the processing circuit including a filter having zeros at the frequency and multiples of the frequency.

In another example, a system includes: a device; a sampling circuit having a sampling input, a sampling output, and a control terminal, the sampling input coupled to the device; a driver circuit having a driver output coupled to the control terminal of the sampling circuit, the driver circuit including a pulse width modulation (PWM) circuit configured to provide a PWM signal at the driver output at a frequency; a sensing circuit having a sense input and a sense output, the sense input coupled to the sampling output; and a processing circuit having a processing input and a processing output. The processing input coupled to the sense output, the processing circuit including a filter having zeros at the frequency and multiples of the frequency.

In yet another example, a circuit includes: a first terminal; a second terminal; a switch between the first and second terminals of the circuit, the switch having a control terminal; a driver circuit having a driver output coupled to the control terminal of the switch, the driver circuit including a PWM circuit configured to provide a PWM signal at the driver output at a frequency; and a voltage sensing circuit having a first terminal, a second terminal, and a third terminal. The first terminal of the voltage sensing circuit is coupled to the first terminal of the circuit. The second terminal of the voltage sensing circuit is coupled to the second terminal of the circuit. The voltage sensing circuit includes an analog-to-digital converter (ADC) and a filter having zeros at the frequency and multiples of the frequency.

### BRIEF DESCRIPTION OF THE DRAWINGS

FIG. 1 is a schematic diagram showing an example system including a sensing circuit and circuits to provide pulse width modulation (PWM) harmonics filtering.

FIGS. 2A and 2B are schematic diagrams illustrating example sensing systems with harmonics filtering.

FIGS. 3A to 3C are diagrams showing the spectral behavior of an example sampling operation with harmonics filtering.

FIGS. 4A and 4B are schematic diagrams showing other example sensing systems with harmonics filtering.

FIGS. 5A to 5C are diagrams showing the spectral behavior of an example sampling operation with harmonics filtering.

FIG. 6 is a schematic diagram showing an example sensing system with a harmonics filtering operation.

FIG. 7 is a schematic diagram showing an example filter to support a harmonics filtering operation.

FIGS. 8A to 8C are diagrams showing the spectral behavior of an example sampling operation with harmonics filtering.

FIGS. 9A and 9B are diagrams showing an example sensing system with harmonics filtering.

FIG. 10 is a graph showing example frequency spectrums of outputs of sampling operations with different harmonics filtering.

### DETAILED DESCRIPTION

The same reference numbers or other reference designators are used in the drawings to designate the same or similar features. Such features may be the same or similar either by function and/or structure.

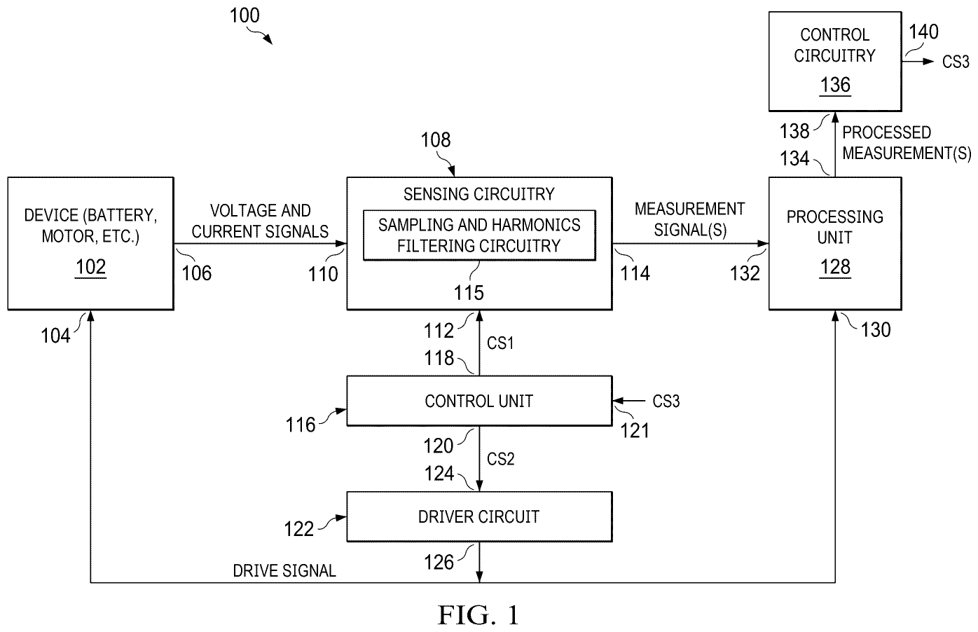

FIG. 1 is a block diagram showing an example system 100 including a sensing circuitry 108 having a sampling and harmonics filtering circuitry 115. The system 100 includes a device 102, the sensing circuitry 108, a control unit 116, a driver circuit 122, a processing unit 128, and control circuitry 136. The device 102 has a first terminal 104 and second terminals 106. The sensing circuitry 108 has first terminals 110, a second terminal 112, and third terminals 114. The control unit 116 has a first terminal 118, a second terminal 120, and a third terminal 121. The driver circuit 122 has a first terminal 124 and a second terminal 126. The processing unit 128 has a first terminal 130, second terminals 132, and third terminals 134. The control circuitry 136 has first terminals 138 and a second terminal 140.

In the example of FIG. 1, the device 102 may be a charge storage device (e.g., a battery), a motor, or another electronic device that can provide a response signal to a drive signal (or an excitation signal). As shown, the second terminals 106 of the device 102 are coupled to the first terminals 110 of the sensing circuitry 108. The second terminal 112 of the sensing circuitry 108 is coupled to the first terminal 118 of the control unit 116. The second terminal 120 of the control unit 116 is coupled to the first terminal 124 of the driver circuit 122. The third terminal 121 of the control unit 116 is coupled to the second terminal 140 of the control circuitry 136. The second terminal 126 of the driver circuit 122 is coupled to the first terminal 104 of the device 102 and the first terminal 130 of the processing unit 128. The second terminals 132 of the processing unit 128 are coupled to the third terminals 114 of the sensing circuitry 108. The third terminals 134 of the processing unit 128 are coupled to the first terminals 138 of the control circuitry 136.

In some examples, the control unit 116 operates to: receive a control signal CS3 at the third terminal 121; provide a control signal CS1 (e.g., a sampling clock signal) at the first terminal 118 responsive to the control signal CS3; and provide a control signal CS2 (e.g., an excitation frequency control signal) at the second terminal 120 responsive to the control signal CS3. In some examples, the driver circuit 122 operates to: receive CS2 at the first terminal 124; and provide a drive signal (or an excitation signal), which can also be buffered, at the second terminal 126 responsive to CS2. In some examples, device 102 operates to: receive the drive signal at the first terminal 104; and provide a response signal, such as voltage and currents signals, at the second terminals 106 responsive to the drive signal. The drive signal can be in the form of a modulated signal, such as a pulse width modulation (PWM) signal.

In some examples, the sensing circuitry 108 operates to: receive the voltage and/or current signals at the first terminal 110; receive CS1 at the second terminal 112; generate samples of the voltage and/or current signals based on CS1 using the sampling and harmonics filtering circuitry 115; perform harmonics filtering on the samples based on CS1 using the sampling and harmonics filtering circuitry 115; and provide measurement signal(s) at the third terminals 114 responsive to results of the sampling and harmonics filtering circuitry 115. In some examples, the sampling and harmonics filtering circuitry 115 can suppress or attenuate harmonic components in the sampled voltage and current signals, where the harmonic components are introduced by the PWM drive signal provided by driver circuit 122.

In some examples, the processing unit 128 operates to: receive drive signal at the first terminal; receive the measurement signal(s) at the second terminals 132; and provide processed measurement(s) at the third terminals 134 responsive to the measurement signals(s) and parameter(s) of the buffered drive signal (e.g., the frequency of the buffered drive signal). The control circuitry 136 operates to: receive the processed measurement(s) at the first terminal 138; and provide the control signal CS3 at the second terminal 140 responsive to the processed measurement(s). In some examples, the processing measurement(s) is an impedance measurement based on filtered voltage and current signals included with the measurement signal(s).

In some examples, the device 102 is a motor and the control signal CS3 is used for motor control. In some examples, the device 102 is a battery and the control signal CS3 is used to adjust a battery charge state (on/off), battery charge current, or other battery system control options.

In some examples, the device 102 is a rechargeable battery. Such rechargeable batteries may be used to power different electrical and portable electronic devices such as electric vehicles, laptop computers, and mobile phones. Battery behavior varies while supplying current depending on battery condition as well as environmental effects. Prediction of battery behavior during its run time is important to manage and improve the battery power supplied to these devices. The battery condition is often characterized by the level of available charge, known as state-of-charge (SOC), and the percentage of useful charge/discharge cycles that remain, known as state-of-health (SOH).

The battery impedance spectrum, which is based on a ratio between the battery cell voltage and current in the frequency domain, has a strong correlation to battery SOC, SOH, and internal temperature. Measurement of battery impedance spectra in order to characterize their behavior is frequently referred to as electrochemical impedance spectroscopy (EIS). EIS measurements can be used to infer the SOC, SOH, or temperature parameters from the measured impedance spectra through generated battery models that characterize battery's behavior.

EIS measurements may be performed using an excitation circuit (e.g., the driver circuit 122) to generate sinusoidal current to excite sense operations. The excitation signal may be a single sinusoidal signal, or a combination of several sinusoids. The control signal CS2 may control the timing, amplitude and frequency of the excitation signal. The battery voltage output in response to the excitation signal is measured by the sensing circuitry 108. In some examples, the excitation signal (from the driver circuit 122) and resulting measurement signals (from the sensing circuitry 108) may be sampled and digitally processed by the processing unit 128 such as a MCU or dedicated hardware. In some examples, the processing unit 128 may include sampling circuitry to obtain excitation signal samples and measurement signal samples. In other examples, the sensing circuitry 108 includes sampling circuitry to provide digital measurement signal(s) to the processing unit 128. In some examples, sampling circuitry to provide excitation signal samples is between the driver circuit 122 and the processing unit 128. In some examples, regardless of how the measurement signal(s) samples and excitation signal samples are obtained, the processing unit 128 may operate to compute the battery impedance spectrum based on computing the frequency domain representations of the current and voltage signals.

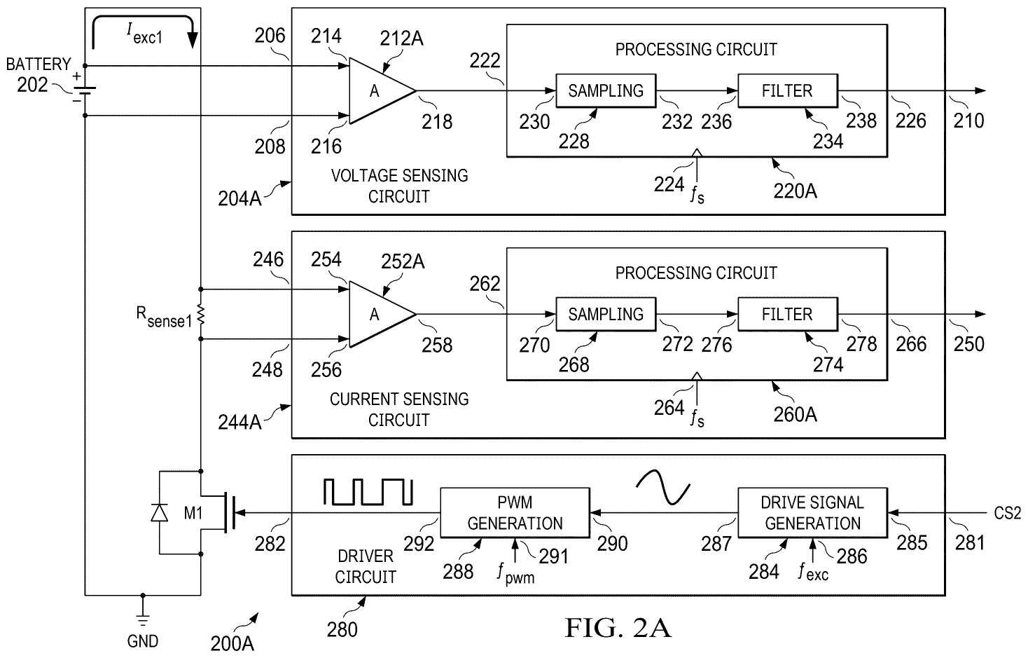

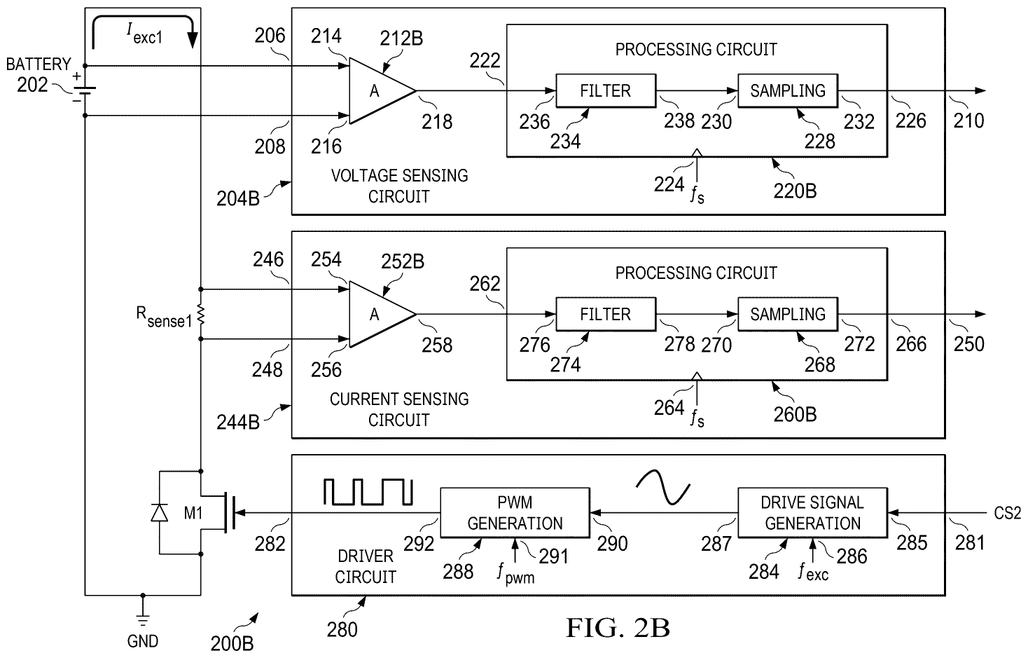

FIG. 2A and FIG. 2B are schematic diagrams illustrating example sensing systems 200A and 200B with harmonics filtering. In the example of FIG. 2A, the sensing system 200A is an EIS measurement system for a battery 202. In other examples, the battery 202 may be replaced by a motor or other electronic device. As shown, the sensing system 200A includes a sense resistor Rₛₑₙₛₑ₁, a transistor M1, a voltage sensing circuit 204A, a current sensing circuit 244A, and a driver circuit 280. The sense resistor Rₛₑₙₛₑ₁, the transistor M1, the voltage sensing circuit 204A, and the current sensing circuit 244A are example components of the sensing circuitry 108 in FIG. 1. The driver circuit 280 is an example of the driver circuit 122 in FIG. 1.

As shown, the voltage sensing circuit 204A has a first terminal 206, a second terminal 208, and a third terminal 210. The voltage sensing circuit 204A includes a first amplifier 212A and a first processing circuit 220A, which includes sampling and harmonics filtering circuitry. The first amplifier 212A has a first terminal 214, a second terminal 216, and a third terminal 218. The first processing circuit 220A has a first terminal 222, a second terminal 224, and a third terminal 226. The first processing circuit 220A is an example of the sampling and harmonics filtering circuitry 115 in FIG. 1. In some examples, the first processing circuit 220A includes first sampling circuitry 228 and a first filter 234. The first sampling circuitry 228 has a first terminal 230 and a second terminal 232. The first filter 234 has a first terminal 236 and a second terminal 238. In the example of FIG. 2A, the first terminal 236 of the first filter 234 is coupled to the second terminal 232 of the first sampling circuitry 228 to perform filtering on samples provided by first sampling circuitry 228.

In the example of FIG. 2A, the first terminal 206 of the voltage sensing circuit 204A is coupled to a first terminal of the battery 202. The second terminal 208 of the voltage sensing circuit 204A is coupled to a second terminal of the battery 202. The third terminal 210 of the voltage sensing circuit 204A is coupled to a processing unit (e.g., the processing unit 128 in FIG. 1).

The first terminal 214 of the first amplifier 212A is coupled to the first terminal 206 of the voltage sensing circuit 204A. The second terminal 216 of the first amplifier 212A is coupled to the second terminal 208 of the voltage sensing circuit 204A. The third terminal 218 of the first amplifier 212A is coupled to the first terminal 222 of the first processing circuit 220A and the first terminal 230 of the first sampling circuitry 228. In FIG. 2A, the second terminal 232 of the first sampling circuitry 228 is coupled to the first terminal 236 of the first filter 234. The second terminal 238 of the first filter 234 is coupled to the third terminal 226 of the first processing circuit 220A and the third terminal 210 of the voltage sensing circuit 204A. The second terminal 224 of the first processing circuit 220A is coupled to a sampling clock source (not shown). In the example of FIG. 2A, the first sampling circuitry 228 provides samples of the output from the first amplifier 212A, and the first filter 234 performs filtering on the samples provided by the first sampling circuitry 228.

The current sensing circuit 244A has a first terminal 246, a second terminal 248, and a third terminal 250. The current sensing circuit 244A includes a second amplifier 252A and a second processing circuit 260A, which includes sampling and harmonic filtering circuitry. The second amplifier 252A has a first terminal 254, a second terminal 256, and a third terminal 258. The second processing circuit 260A has a first terminal 262, a second terminal 264, and a third terminal 266. The second processing circuit 260A is an example of the sampling and harmonics filtering circuitry 115 in FIG. 1. In some examples, the second processing circuit 260A includes second sampling circuitry 268 and a second filter 274. The second sampling circuitry 268 has a first terminal 270 and a second terminal 272. The second filter 274 has a first terminal 276 and a second terminal 278.

In the example of FIG. 2A, the first terminal 246 of the current sensing circuit 244A is coupled to the first terminal of the sense resistor Rₛₑₙₛₑ₁. The second terminal 248 of the current sensing circuit 244A is coupled to a second terminal of the sense resistor Rₛₑₙₛₑ₁. The third terminal 250 of the current sensing circuit 244A is coupled to a processing unit (e.g., the processing unit 128 in FIG. 1).

The first terminal 254 of the second amplifier 252A is coupled to the first terminal 246 of the current sensing circuit 244A. The second terminal 256 of the second amplifier 252A is coupled to the second terminal 248 of the current sensing circuit 244A. The third terminal 258 of the second amplifier 252A is coupled to the first terminal 262 of the second processing circuit 260A. In FIG. 2A, the first terminal 270 of the second sampling circuitry 268 is coupled to the first terminal 262 of the second processing circuit 260A. The second terminal 272 of the second sampling circuitry 268 is coupled to the first terminal 276 of the second filter 274. The second terminal 278 of the second filter 274 is coupled to the third terminal 266 of the second processing circuit 260A and the third terminal 250 of the current sensing circuit 244A. The second terminal 264 of the second processing circuit 260A is coupled to a sampling clock source (not shown). In the example of FIG. 2A, the second sampling circuitry 268 provides samples of the output from the second amplifier 252A, and the second filter 274 performs filtering on the samples provided by the second sampling circuitry 268.

In the example of FIG. 2B, the sensing system 200B is an EIS measurement system for the battery 202. In other examples, the battery 202 may be replaced by a motor or other electronic device. As shown, the sensing system 200B includes the sense resistor Rₛₑₙₛₑ₁, the transistor M1, a voltage sensing circuit 204B, a current sensing circuit 244B, and the driver circuit 280. The sense resistor Rₛₑₙₛₑ₁, the transistor M1, the voltage sensing circuit 204B, and the current sensing circuit 244B are example components of the sensing circuitry 108 in FIG. 1. The driver circuit 280 is an example of the driver circuit 122 in FIG. 1.

As shown, the voltage sensing circuit 204B has the first terminal 206, the second terminal 208, and the third terminal 210. The voltage sensing circuit 204B includes a first amplifier 212B and a first processing circuit 220B, which includes sampling and harmonics filtering circuitry. The first processing circuit 220B has the first terminal 222, the second terminal 224, and the third terminal 226. The first processing circuit 220B is an example of the sampling and harmonics filtering circuitry 115 in FIG. 1. In some examples, the first processing circuit 220B includes the first filter 234 and the first sampling circuitry 228 in reverse order relative to the voltage sensing circuit 204A in FIG. 2A. More specifically, in the example of FIG. 2B, the first terminal 236 of the first filter 234 is coupled to the first terminal 222 of the first processing circuit 220B, and the second terminal 238 of the first filter 234 is coupled to the first terminal 230 of the first sampling circuitry 228. The second terminal 232 of the first sampling circuitry 228 is coupled to third terminal 226 of the first processing circuitry 220B and the third terminal 210 of the voltage sensing circuit 204B. In the example of FIG. 2B, the first filter 234 performs filtering on the output of first amplifier 212B, and the first sampling circuitry 228 generates samples from the filtered output of first amplifier 212B.

In FIG. 2B, the first terminal 276 of the second filter 274 is coupled to the first terminal 262 of the second processing circuit 260B, the first terminal 270 of the second sampling circuitry 268 is coupled to the second terminal 278 of the second filter 274, and the second terminal 272 of the second sampling circuitry 268 is coupled to the third terminal 266 of the second processing circuit 260B and the third terminal 250 of the current sensing circuit 244B. In the example of FIG. 2B, the second filter 274 performs filtering on the output of the second amplifier 252B and the second sampling circuitry 268 generates samples from the filtered output of the second filter 274.

For both the sensing system 200A of FIG. 2A and the sensing system 200B of 2B, the driver circuit 280 has a first terminal 281 and a second terminal 282. The driver circuit 280 includes drive signal generation circuitry 284 and PWM generation circuitry 288. The drive signal generation circuitry 284 has a first terminal 285, a second terminal 286, and a third terminal 287. The PWM generation circuitry 288 has a first terminal 290, a second terminal 291, and a third terminal 292.

For both the sensing system 200A of FIG. 2A and the sensing system 200B of 2B, the first terminal 281 of the driver circuit 280 may be coupled to a control unit (e.g., the control unit 116 in FIG. 1) and the first terminal 285 of the drive signal generation circuitry 284. The second terminal 286 receives a control signal with a frequency f_{exc}. The third terminal 287 of the drive signal generation circuitry 284 is coupled to the first terminal 290 of the PWM generation circuitry 288. The second terminal 291 of the PWM generation circuitry 288 receives a control signal with a frequency f_{pwm}. The third terminal 292 of the PWM generation circuitry 288 is coupled to the second terminal 282 of the driver circuit 280 and the control terminal of the transistor M1. In the example of FIG. 2, the first terminal of the battery 202 is coupled to the first terminal of the sense resistor Rₛₑₙₛₑ₁. The second terminal of the sense resistor Rₛₑₙₛₑ₁ is coupled to a first terminal of the transistor M1. The second terminal of the transistor M1 is coupled to ground and the second terminal of the battery 202. For both the sensing system 200A of FIG. 2A and the sensing system 200B of 2B, the driver circuit 280 operates to: receive the control signal CS2 at the first terminal 281 and generate a drive signal at the second terminal 282 responsive to the control signal CS2, operations of the drive signal generation circuitry 284, and operations of the PWM generation circuitry 288. In the examples of FIGS. 2A and 2B, the drive signal has the frequency f_{pwm}. More specifically, in some examples, the drive signal generation circuitry 284 operates to: receive the control signal CS2 at the first terminal 285; receive a control signal with frequency f_{exc} at the second terminal 286; and generate a sinusoidal signal (including one or more sinusoids) at the third terminal 287 responsive to the control signal CS2 and the control signal with frequency f_{exc}. In some examples, CS2 may indicate the excitation frequency f_{exc} instead of a separate control signal. In some examples, the PWM generation circuitry 288 operates to: receive the sinusoidal signal at the first terminal 290; receive a control signal with frequency f_{pwm} at the second terminal 291; and generate the drive signal at the third terminal 292 responsive to the sinusoidal signal and the control signal with frequency f_{pwm}. The drive signal is used to control on/off intervals of the transistor M1. When the transistor M1 is turned on, a current I_{exc1} flows from the first terminal of the battery 202 to ground and sensing operations are performed by the voltage sensing circuit 204A and the current sensing circuit 244A in FIG. 2A, or the voltage sensing circuit 204B and the current sensing circuit 244B in FIG. 2B.

In the sensing system 200A of FIG. 2A, the voltage sensing circuit 204A operates to: receive a first voltage at the first terminal 206; receive a second voltage at the second terminal 208; and provide a first output signal (e.g., a voltage measurement signal) responsive to the first voltage, the second voltage, the operations of the first amplifier 212A, and the operations of the first processing circuit 220A. More specifically, the first amplifier 212A operates to: receive the first voltage at the first terminal 214; receive the second voltage at the second terminal 216; and provide a first amplified signal at the third terminal 218 responsive to the difference between the first voltage level and the second voltage level. The first processing circuit 220A operates to: receive the first amplified signal at the first terminal 222; receive a sampling clock signal at the second terminal 224; and provide the first output signal at the third terminal 226 responsive to the first amplified signal, the sampling clock signal, the operations of the first sampling circuitry 228, and the operations of the first filter 234. In some examples, the first sampling circuitry 228 operates to: receive the first amplified signal at the first terminal 230; receive the sampling clock signal; and provide first samples of the first amplified signal based on the sampling clock signal. In some examples, the first filter 234 operates to: receive the first samples at the first terminal 236; perform filtering operations on the first samples; and provide the first output signal at the second terminal 238 responsive to the first samples and the filtering operations.

In the sensing system 200A of FIG. 2A, the current sensing circuit 244A operates to: receive the first voltage at the first terminal 246; receive a third voltage at the second terminal 248; and provide a second output signal (e.g., a current measurement signal) responsive to the first voltage, the third voltage, the operations of the second amplifier 252A, and the operations of the second processing circuit 260A. More specifically, the second amplifier 252A operates to: receive the first voltage at the first terminal 254; receive the third voltage at the second terminal 256; and provide a second amplified signal at the third terminal 258 responsive to the difference between the first voltage and the third voltage. The second processing circuit 260A operates to: receive the second amplified signal at the first terminal 262; receive the sampling clock signal at the second terminal 264; and provide the second output signal at the third terminal 266 responsive to the second amplified signal, the sampling clock signal, the operations of the second sampling circuitry 268, and the operations of the second filter 274. In the example of FIG. 2A, the second sampling circuitry 268 operates to: receive the second amplified signal at the first terminal 270; receive the sampling clock signal; and provide second samples of the second amplified signal based on the sampling clock signal. Also, the second filter 274 operates to: receive the second samples at the first terminal 276; perform filtering operations on the second samples; and provide the second output signal at the second terminal 278 responsive to the second samples and the filtering operations.

In the sensing system 200B of FIG. 2B, the voltage sensing circuit 204B operates to: receive a first voltage at the first terminal 206; receive a second voltage at the second terminal 208; and provide a first output signal (e.g., a voltage measurement signal) responsive to the first voltage, the second voltage, the operations of the first amplifier 212B, and the operations of the first processing circuit 220B. More specifically, the first amplifier 212B operates to: receive the first voltage at the first terminal 214; receive the second voltage at the second terminal 216; and provide a first amplified signal at the third terminal 218 responsive to the difference between the first voltage level and the second voltage level. The first processing circuit 220B operates to: receive the first amplified signal at the first terminal 222; receive a sampling clock signal at the second terminal 224; and provide the first output signal at the third terminal 226 responsive to the first amplified signal, the sampling clock signal, the operations of the first filter 234, and the operations of the first sampling circuitry 228. In the example of FIG. 2B, the first filter 234 operates to: receive the first amplified signal at the first terminal 236; perform filtering operations on the first amplified signal; and provide a first filtered results at the second terminal 238 responsive to the first amplified signal and the filtering operations. The first sampling circuitry 228 operates to: receive the first filtered results at the first terminal 230; receive the sampling clock signal; and provide the first output signal at the second terminal 232, where the first output signal includes first samples of the first filtered results based on the sampling clock signal.

In the example of FIG. 2B, the current sensing circuit 244B operates to: receive the first voltage at the first terminal 246; receive a third voltage at the second terminal 248; and provide a second output signal (e.g., a current measurement signal) responsive to the first voltage, the third voltage, the operations of the second amplifier 252B, and the operations of the second processing circuit 260B. More specifically, the second amplifier 252B operates to: receive the first voltage at the first terminal 254; receive the third voltage at the second terminal 256; and provide a second amplified signal at the third terminal 258 responsive to the difference between the first voltage and the third voltage. The second processing circuit 260B operates to: receive the second amplified signal at the first terminal 262; receive the sampling clock signal at the second terminal 264; and provide the second output signal at the third terminal 266 responsive to the second amplified signal, the sampling clock signal, the operations of the second filter 274, and the operations of the second sampling circuitry 268. In the example of FIG. 2B, the second filter 274 operates to: receive the second amplified signal at the first terminal 276; perform filtering operations on the second amplified signal; and provide second filtered results at the second terminal 278 responsive to the second amplified signal and the filtering operations. The second sampling circuitry 268 operates to: receive the second filtered results at the first terminal 270; receive the sampling clock signal; and provide the second output signal at the second terminal 272, where the second output signal includes second samples of the second filtered results based on the sampling clock signal.

In both of sensing systems 200A and 200B of FIGS. 2A and 2B, the driver circuit 280 is responsible for generating an excitation signal for the battery 202 at the excitation frequency f_{exc} using PWM. In some examples, the excitation signal is sinusoidal signal at the desired excitation frequency f_{exc}. The sinusoidal signal is used to modulate the pulse width of a square wave signal with frequency f_{PWM}. The PWM signal is used to control the transistor M1, which may be field-effect transistor (FET), connected to the battery 202 through the sense resistor Rₛₑₙₛₑ₁. By controlling the transistor M1, the PWM signal controls the current excitation waveform I_{exc1}, which affects related sense operations.

In some examples, a voltage sensing circuit (e.g., the voltage sensing circuit 204A in FIG. 2A, or the voltage sensing circuit 204B in FIG. 2B) senses the voltage response of the battery 202 to the excitation current signal at frequency f_{exc}. In addition, a voltage sensing circuit may operate to: sample the voltage response signal at the sampling frequency fₛ; and convert the sampled voltage response into the digital domain data for post-processing. In some examples, the battery voltage response signal includes voltage sense results at the low frequency f_{exc} in addition to PWM harmonics (high frequency components at the combinations of n*f_{PWM}±m*f_{exc} where n is a positive integer (i.e., 1,2, . . . , etc.) and m is a non-negative integer (i.e. 0,1,2, . . . etc.). In some examples, PWM harmonics are filtered by a first processing circuit (e.g., the first processing circuit 220A in FIG. 2A, or the first processing circuit 220B in FIG. 2B).

In some examples, a current sensing circuit (e.g., the current sensing circuit 244A in FIG. 2A, or the current sensing circuit 244B in FIG. 2B) senses I_{exc1}. More specifically, a current sensing circuit may operate to: sample a voltage across the sense resistor Rₛₑₙₛₑ₁ at the sampling frequency fₛ; and convert the sampled voltage into the digital domain data for post-processing. In some examples, the voltage signal includes current sense results at the low frequency f_{exc} in addition to PWM harmonics (high frequency components at the combinations of n*f_{PWM}±m*f_{exc}, where n is 1,2, . . . etc. and m is 0,1,2, . . . etc.). In some examples, PWM harmonics are filtered by a second processing circuit (e.g., the second processing circuit 260A in FIG. 2A, or the second processing circuit 260B in FIG. 2B).

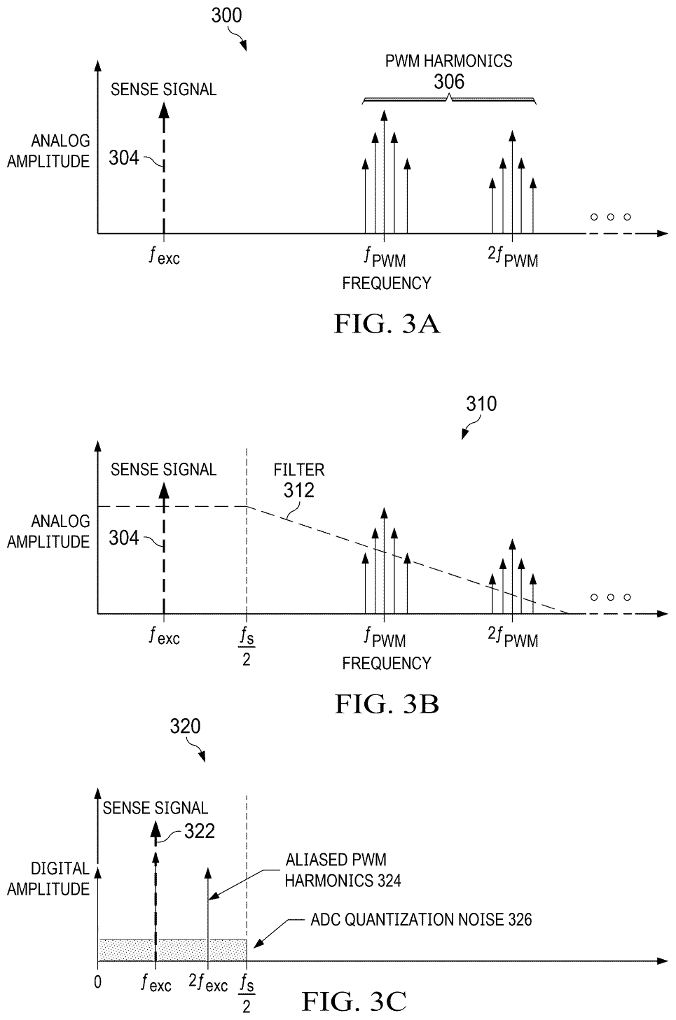

FIGS. 3A to 3C are diagrams 300, 310, and 320 showing the spectral behavior of an example sampling operation with PWM harmonics filtering. In the example of FIGS. 3A to 3C, an excitation frequency occurs at f_{exc}=f_{PWM}−k·fₛ, where k is a positive integer (i.e., 1, 2, . . . , etc.). With this excitation frequency, the PWM harmonics will alias back and interfere with the discrete Fourier transform (DFT) measurement at the excitation frequency.

In the diagram 300 of FIG. 3A, a sense signal 304 at frequency f_{exc} and PWM harmonics 306 at frequencies f_{PWM} and 2f_{PWM} are represented. In the diagram 310 of FIG. 3B, a filter 312 is applied, which results in some filtering of the PWM harmonics 306. In the diagram 320 of FIG. 3C, a digitized sense signal 322, aliased PWM harmonics 324, and ADC quantization noise 326 are represented. In some examples, the digitized sense signal 322, the aliased PWM harmonics 324, and the ADC quantization noise 326 in the diagram 320 are the result of discrete Fourier transform operations applied to the filtered signal of the diagram 310 in FIG. 3B. In the diagram 320, the aliased PWM harmonics 324 are at f_{alias_1}=f_{alias_2}−f_{exc}, f_{alias_2}=f_{PWM}−k·fₛ, and f_{alias_3}=f_{alias_2}+f_{exc}. As shown, the amplitude of the aliased PWM harmonics 324 is greater than the ADC quantization noise 326 and results in some interference with the digitized sense signal 322 at f_{exc}.

In some examples, PWM harmonics filtering circuitry (e.g., the sampling and harmonics filtering circuitry 115 of FIG. 1, the first processing circuits 220A and 220B of FIGS. 2A and 2B, or the second processing circuits 260A and 260B of FIGS. 2A and 2B) may use a simple, low cost, scalable solution to handle the aliasing of PWM harmonics. In some examples, PWM harmonics filtering circuitry (e.g., the sampling and harmonics filtering circuitry 115 of FIG. 1, the first processing circuit 220A and 220B of FIGS. 2A and 2B, or the second processing circuits 260A and 260B of FIGS. 2A and 2B) minimizes (or at least substantially attenuate) PWM harmonics while imposing little or no limit on the excitation and sampling frequencies, resulting in more accurate sense results (e.g., impedance measurements) and related control operations.

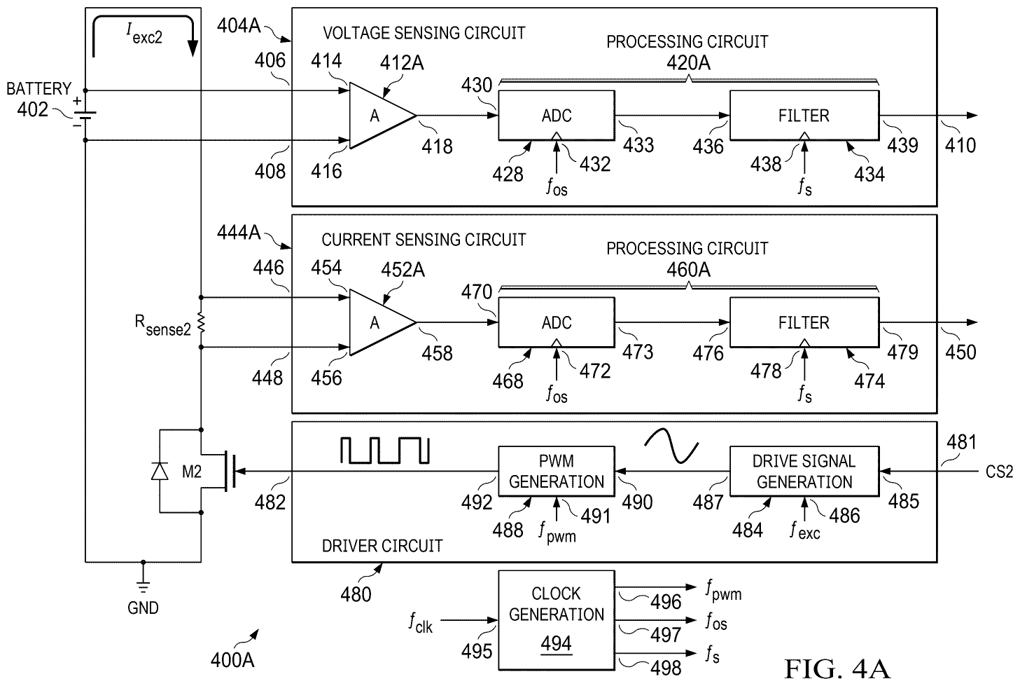

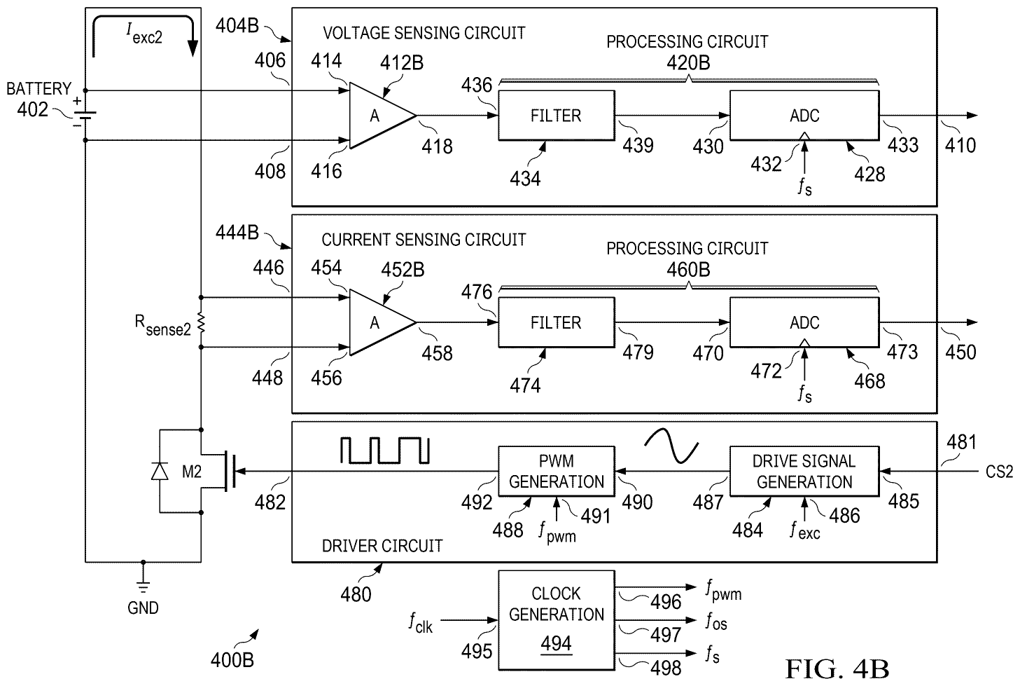

FIGS. 4A and 4B are schematic diagrams showing other example sensing systems 400A and 400B with harmonics filtering. In the example of FIG. 4A, the sensing system 400A is an EIS measurement system for a battery 402. In other examples, the battery 402 may be replaced by a motor or other electronic device. As shown, the sensing system 400A includes a sense resistor Rₛₑₙₛₑ₂, a transistor M2, a voltage sensing circuit 404A, a current sensing circuit 444A, a driver circuit 480, and clock generation circuitry 494. The sense resistor Rₛₑₙₛₑ₂, the transistor M2, the voltage sensing circuit 404A, and the current sensing circuit 444A are example components of the sensing circuitry 108 in FIG. 1. The driver circuit 480 is an example of the driver circuit 122 in FIG. 1. The clock generation circuitry 494 is an example component of the control unit 116 in FIG. 1. In the examples of FIGS. 4A and 4B, the clock generation circuitry 494 has a first terminal 495, a second terminal 496, a third terminal 497, and a fourth terminal 498.

As shown, the voltage sensing circuit 404A has a first terminal 406, a second terminal 408, and a third terminal 410. The voltage sensing circuit 404A includes a first amplifier 412A and a first processing circuit 420A, which includes sampling and harmonics filtering circuitry. The first processing circuit 420A is an example of the sampling and harmonics filtering circuitry 115 in FIG. 1. In the example of FIG. 4A, the first amplifier 412A has a first terminal 414, a second terminal 416, and a third terminal 418. The first processing circuit 420A includes a first analog-to-digital converter (ADC) 428 and a first filter 434. The first ADC 428 has a first terminal 430, a second terminal 432, and a third terminal 433. The first filter 434 has a first terminal 436, a second terminal 438, and a third terminal 439. In some examples, the first filter 434 can be a notch filter, a sinc filter, a cascaded integrator-comb filter (CIC), etc., having zeros (or otherwise providing substantial attenuation) at n times of the sampling frequency fₛ and/or the PWM frequency f_{pwm}, where n is one or more. In some examples, the first filter 434 more effectively attenuates the fundamental PWM frequency and the PWM harmonics, which are integer multiples of the fundamental PWM frequency, in the sampled voltage and current signals compared to the first filter 234 and the second filter 274 shown in FIGS. 2A and 2B. In some examples, the first filter 434 may be a digital filter that operates on digital samples generated by first ADC 428.

The first terminal 406 of the voltage sensing circuit 404A is coupled to the first terminal of the battery 402. The second terminal 408 of the voltage sensing circuit 404A is coupled to a second terminal of the battery 402. The third terminal 410 of the voltage sensing circuit 404A is coupled to a processing unit (e.g., the processing unit 128 in FIG. 1).

The first terminal 414 of the first amplifier 412A is coupled to the first terminal 406 of the voltage sensing circuit 404A. The second terminal 416 of the first amplifier 412A is coupled to the second terminal 408 of the voltage sensing circuit 404A. The third terminal 418 of the first amplifier 412A is coupled to the first terminal 430 of the first ADC 428. The second terminal 432 of the first ADC 428 is coupled to the third terminal 497 of the clock generation circuitry 494 and receives an oversampling clock signal with oversampling frequency fₒₛ. The third terminal 433 of the first ADC 428 is coupled to the first terminal 436 of the first filter 434. The second terminal 438 of the first filter 434 is coupled to the fourth terminal 498 of the clock generation circuitry 494. The third terminal 439 of the first filter 434 is coupled to the third terminal 410 of the voltage sensing circuit 404A.

The current sensing circuit 444A has a first terminal 446, a second terminal 448, and a third terminal 450. The current sensing circuit 444A includes a second amplifier 452A and a second processing circuit 460A, which includes sampling and harmonics filtering circuitry. The second processing circuit 460A is an example of the sampling and harmonics filtering circuitry 115 in FIG. 1. In the example of FIG. 4A, the second amplifier 452A has a first terminal 454, a second terminal 456, and a third terminal 458. The second processing circuit 460A includes a second ADC 468 and a second filter 474. The second ADC 468 has a first terminal 470, a second terminal 472, and a third terminal 473. The second filter 474 has a first terminal 476, a second terminal 478, and a third terminal 479. In some examples, the second filter 474 can be a notch filter, a sinc filter, etc., having zeros (or otherwise providing substantial attenuation) at n times of the sampling frequency fₛ and/or the PWM frequency f_{pwm}, where n is one or more. The second filter 474 can more effectively attenuate the fundamental PWM frequency and the PWM harmonics, which are integer multiples of the fundamental PWM frequency, in the sampled voltage and current signals compared to the first filter 234 and second filter 274 shown in FIGS. 2A and 2B. In some examples, the second filter 474 can be a digital filter that operates on digital samples generated by the second ADC 468.

The first terminal 446 of the current sensing circuit 444A is coupled to the first terminal of the sense resistor Rₛₑₙₛₑ₂. The second terminal 448 of the current sensing circuit 444A is coupled to the second terminal of the sense resistor Rₛₑₙₛₑ₂. The third terminal 450 of the current sensing circuit 444A is coupled to a processing unit (e.g., the processing unit 128 in FIG. 1).

The first terminal 454 of the second amplifier 452A is coupled to the first terminal 446 of the current sensing circuit 444A. The second terminal 456 of the second amplifier 452A is coupled to the second terminal 448 of the current sensing circuit 444A. The third terminal 458 of the second amplifier 452A is coupled to the first terminal 470 of the second ADC 468. The second terminal 472 of the second ADC 468 is coupled to the third terminal 497 of the clock generation circuitry 494. The third terminal 473 of the second ADC 468 is coupled to the first terminal 476 of the second filter 474. The second terminal 478 of the second filter 474 is coupled to the fourth terminal 498 of the clock generation circuitry 494. The third terminal 479 of the second filter 474 is coupled to the third terminal 450 of the current sensing circuit 444A.

In the example of FIG. 4B, the sensing system 400B is an EIS measurement system for the battery 402. In other examples, the battery 402 may be replaced by a motor or other electronic device. As shown, the sensing system 400B includes the sense resistor Rₛₑₙₛₑ₂, the transistor M2, a voltage sensing circuit 404B, a current sensing circuit 444B, the driver circuit 480, and the clock generation circuitry 494. In some examples, such as the example of FIG. 4B, the oversampling clock signal is not used and the third terminal 497 of the clock generation circuitry 494 may be omitted. The sense resistor Rₛₑₙₛₑ₂, the transistor M2, the voltage sensing circuit 404B, and the current sensing circuit 444B are example components of the sensing circuitry 108 in FIG. 1. The driver circuit 480 is an example of the driver circuit 122 in FIG. 1. The clock generation circuitry 494 is an example component of the control unit 116 in FIG. 1.

As shown, the voltage sensing circuit 404B has the first terminal 406, the second terminal 408, and the third terminal 410. The voltage sensing circuit 404B includes a first amplifier 412B and a first processing circuit 420B, which includes sampling and harmonics filtering circuitry. The first processing circuit 420B is an example of the sampling and harmonics filtering circuitry 115 in FIG. 1. In the example of FIG. 4B, the first amplifier 412B has the first terminal 414, the second terminal 416, and the third terminal 418. The first processing circuit 420B includes the first filter 434 and the first ADC 428 in reverse order relative to the first processing circuit 420A in FIG. 4A. In the example of FIG. 4B, the first filter 434 can be a notch filter, a sinc filter, a cascaded integrator-comb filter (CIC), etc., having zeros (or otherwise providing substantial attenuation) at n times of the sampling frequency fₛ and/or the PWM frequency f_{pwm}, where n is one or more. In some examples, the first filter 434 more effectively attenuates the fundamental PWM frequency and the PWM harmonics, which are integer multiples of the fundamental PWM frequency, in the sampled voltage and current signals compared to the first filter 234 and the second filter 274 shown in FIGS. 2A and 2B. In the example of FIG. 4B, the first filter 434 may be a digital filter that operates on the first amplified signal output from the first amplifier 412B. The first ADC 428 then digitizes the filtered result from the first filter 434.

In the example of FIG. 4B, the first terminal 406 of the voltage sensing circuit 404B is coupled to the first terminal of the battery 402. The second terminal 408 of the voltage sensing circuit 404B is coupled to a second terminal of the battery 402. The third terminal 410 of the voltage sensing circuit 404B is coupled to a processing unit (e.g., the processing unit 128 in FIG. 1).

In the example of FIG. 4B, the first terminal 414 of the first amplifier 412B is coupled to the first terminal 406 of the voltage sensing circuit 404B. The second terminal 416 of the first amplifier 412B is coupled to the second terminal 408 of the voltage sensing circuit 404B. The third terminal 418 of the first amplifier 412B is coupled to the first terminal 436 of the first filter 434. In the example of FIG. 4B, the second terminal 438 of the first filter 434 may be omitted, and the third terminal 439 of the first filter 434 is coupled to the first terminal 430 of the first ADC 428. The second terminal 432 of the first ADC 428 is coupled to the fourth terminal 498 of the clock generation circuitry 494 and receives a sampling clock signal with sampling frequency fₛ. In different examples, the sampling frequency fₛ used in example of FIG. 4B, may vary from the sampling frequency fₛ of other examples. The third terminal 433 of the first ADC 428 is coupled to the third terminal 410 of the voltage sensing circuit 404B.

The current sensing circuit 444B has the first terminal 446, the second terminal 448, and the third terminal 450. The current sensing circuit 444B includes a second amplifier 452B and a second processing circuit 460B, which includes sampling and harmonics filtering circuitry. The second processing circuit 460B is an example of the sampling and harmonics filtering circuitry 115 in FIG. 1. In the example of FIG. 4B, the second amplifier 452B has the first terminal 454, the second terminal 456, and the third terminal 458. The second processing circuit 460B includes the second filter 474 and the second ADC 468 in reverse order relative to the second processing circuit 460A in FIG. 4A. In the example of FIG. 4B, the second filter 474 may be a notch filter, a sinc filter, etc., having zeros (or otherwise providing substantial attenuation) at n times of the sampling frequency fₛ and/or the PWM frequency f_{pwm}, where n is one or more. The second filter 474 can more effectively attenuate the fundamental PWM frequency and the PWM harmonics, which are integer multiples of the fundamental PWM frequency, in the sampled voltage and current signals compared to the first filter 234 and second filter 274 shown in FIGS. 2A and 2B. In the example of FIG. 4B, the second filter 474 may be a digital filter that operates on the second amplified signal output from the second amplifier 452B. The second ADC 468 then digitizes the filtered result from the second filter 474.

In the example of FIG. 4B, the first terminal 446 of the current sensing circuit 444B is coupled to the first terminal of the sense resistor Rₛₑₙₛₑ₂. The second terminal 448 of the current sensing circuit 444B is coupled to the second terminal of the sense resistor Rₛₑₙₛₑ₂. The third terminal 450 of the current sensing circuit 444B is coupled to a processing unit (e.g., the processing unit 128 in FIG. 1).

In the example of FIG. 4B, the first terminal 454 of the second amplifier 452B is coupled to the first terminal 446 of the current sensing circuit 444B. The second terminal 456 of the second amplifier 452B is coupled to the second terminal 448 of the current sensing circuit 444B. The third terminal 458 of the second amplifier 452B is coupled to the first terminal 476 of the second filter 474. In the example of FIG. 4B, the second terminal 478 may be omitted, and the third terminal 479 of the second filter 474 is coupled to the first terminal 470 of the second ADC 468. The second terminal 472 of the second ADC 468 is coupled to the fourth terminal 498 of the clock generation circuitry 494 and receives a sampling clock signal with sampling frequency fₛ. The third terminal 473 of the second ADC 468 is coupled to the third terminal 450 of the current sensing circuit 444B.

With the sensing system 400B in FIG. 4B, the first filter 434 is coupled between third terminal 418 of the first amplifier 412B and the first terminal 430 of the first ADC 428, where the filtering is performed on the output of the first amplifier 412B, and the first ADC 428 can generate samples from the filtered results. In FIG. 4B, the first filter 434 can include passive elements (e.g., resistor, inductor, capacitor) and/or delay lines to implement a CIC filter. Also, the second filter 474 is coupled between third terminal 458 of the second amplifier 452B and the first terminal 470 of the second ADC 468, where the filtering is performed on the output of the second amplifier 452B, and the second ADC 468 can generate samples from the filtered results. In FIG. 4B, the second filter 474 can include passive elements (e.g., resistor, inductor, capacitor) and/or delay lines to implement a CIC filter.

For both the sensing system 400A of FIG. 4A and the sensing system 400B of 4B, the driver circuit 480 has a first terminal 481 and a second terminal 482. The driver circuit 480 includes drive signal generation circuitry 484 and PWM generation circuitry 488. The drive signal generation circuitry 484 has a first terminal 485, a second terminal 486, and a third terminal 487. The PWM generation circuitry 488 has a first terminal 490, a second terminal 491, and a third terminal 492.

For both the sensing system 400A of FIG. 4A and the sensing system 400B of 4B, the first terminal 481 of the driver circuit 480 may be coupled to a control unit (e.g., the control unit 116 in FIG. 1) and the first terminal 485 of the drive signal generation circuitry 484. The second terminal 486 of the drive signal generation circuitry 484 receives a control signal with frequency f_{exc}. The third terminal 487 of the drive signal generation circuitry 484 is coupled to the first terminal 490 of the PWM generation circuitry 488. The second terminal 491 of the PWM generation circuitry 488 receives a control signal with frequency f_{pwm}. The third terminal 492 of the PWM generation circuitry 488 is coupled to the second terminal 482 of the driver circuit 480 and the control terminal of the transistor M2. For both the sensing system 400A of FIG. 4A and the sensing system 400B of 4B, the first terminal of the battery 402 is coupled to the first terminal of the sense resistor Rₛₑₙₛₑ₂. The second terminal of the sense resistor Rₛₑₙₛₑ₂ is coupled to the first terminal of the transistor M2. The second terminal of the transistor M2 is coupled to ground and the second terminal of the battery 402.

For both the sensing system 400A of FIG. 4A and the sensing system 400B of 4B, the clock generation circuitry 494 operates to: receive a master clock signal at the first terminal 495, the master clock signal having a frequency f_{CLK}; provide a PWM clock signal at the second terminal 496 responsive to the master clock signal, the PWM clock signal having a PWM frequency f_{PWM}; provide an oversampling clock signal at the third terminal 497 responsive to the master clock signal, the oversampling clock signal having an oversampling frequency fₒₛ; and provide a sampling clock signal at the fourth terminal 498 responsive to the master clock signal, the sampling clock signal having a sampling frequency fₛ. In some examples, f_{CLK} may be 10 to 20 MHZ, f_{EXC} may be 1 mHz to 20 kHz, f_{PWM} may be 20 kHz to 1 MHZ, fₒₛ may be 1 Hz to 20 MHZ, and fₛ may be 100 mHz to 2 MHz.

For both the sensing system 400A of FIG. 4A and the sensing system 400B of 4B, the driver circuit 480 operates to: receive the control signal CS2 at the first terminal 481; and generate a drive signal at the second terminal 482 responsive to the control signal CS2, operations of the drive signal generation circuitry 484, and operations of the PWM generation circuitry 488. In the examples of FIGS. 4A and 4B, the drive signal has a frequency f_{pwm}. More specifically, in some examples, the drive signal generation circuitry 484 operates to: receive the control signal CS2 at the first terminal 485; receive a control signal with frequency f_{exc} at the second terminal 486; and generate a sinusoidal signal at the third terminal 487 responsive to the control signal CS2 and the control signal with frequency f_{exc}. In some examples, CS2 may indicate the excitation frequency f_{exc} instead of a separate control signal. In some examples, the PWM generation circuitry 488 operates to: receive the sinusoidal signal at the first terminal 490; receive a control signal with frequency f_{pwm} at the second terminal 491; and generate the drive signal at the third terminal 492 responsive to the sinusoidal signal and the control signal with frequency f_{pwm}. The drive signal is used to control on/off intervals of the transistor M2. When the transistor M2 is turned on, a current I_{exc2} flows from the first terminal of the battery 402 to ground and sensing operations are performed by the voltage sensing circuit 404A and/or the current sensing circuit 444A.

In the sensing system 400A of FIG. 4A, the voltage sensing circuit 404A operates to: receive a first voltage at the first terminal 406; receive a second voltage at the second terminal 408; and provide a first output signal (e.g., a voltage measurement signal) responsive to the first voltage, the second voltage, the operations of the first amplifier 412A, and the operations of the first processing circuit 420A. More specifically, the first amplifier 412A operates to: receive the first voltage at the first terminal 414; receive the second voltage at the second terminal 416; and provide a first amplified signal at the third terminal 418 responsive to the difference between the first voltage and the second voltage. The first processing circuit 420A operates to: receive the first amplified signal; receive the oversampling clock signal; receive the sampling clock signal having a lower frequency than the oversampling clock signal; and provide the first digital output responsive to the first amplified signal, the oversampling clock signal; the sampling clock signal, the operations of the first ADC 428, and the operations of the first filter 434.

In the example of FIG. 4A, the first ADC 428 operates to: receive the first amplified signal at the first terminal 430; receive the oversampling clock signal with frequency fₒₛ at the second terminal 432; and provide first samples of the first amplified signal at the third terminal 433 based on the oversampling clock signal. In some examples, the first filter 434 is a digital filter and operates to: receive the first samples at the first terminal 436; receive the sampling clock signal with frequency fₛ at the second terminal 438; perform filtering operations on the first samples; and provide the first digital output at the third terminal 439 responsive to the first samples, the filtering operations, and the sampling clock signal. In some examples, the first filter 434 is a digital filter implemented in, for example, an application specific integrated circuit (ASIC), a programmable logic circuit such as a field programmable gate array logic (FPGA), or as software instructions in a digital signal processor (DSP).

In the example of FIG. 4A, the current sensing circuit 444A operates to: receive the first voltage at the first terminal 446; receive a third voltage at the second terminal 448; and provide a second output (e.g., a current measurement signal) responsive to the first voltage, the third voltage, the operations of the second amplifier 452A, and the operations of the second processing circuit 460A. More specifically, the second amplifier 452A operates to: receive the first voltage at the first terminal 454; receive the third voltage at the second terminal 456; and provide a second amplified signal at the third terminal 458 responsive to the difference between the first voltage and the third voltage. The second processing circuit 460A operates to: receive the second amplified signal; receive the oversampling clock signal; receive the sampling clock signal; and provide the second output signal responsive to the second amplified signal, the oversampling clock signal, the sampling clock signal, operations of the second ADC 468, and operations of the second filter 474.

In the example of FIG. 4A, the second ADC 468 operates to: receive the second amplified signal at the first terminal 470; receive the oversampling clock signal with frequency fₒₛ at the second terminal 472; and provide second samples of the second amplified signal at the third terminal 473 based on the oversampling clock signal. In the example of FIG. 4A, the second filter 474 may be a digital filter that operates to: receive the second samples at the first terminal 476; receive the sampling clock signal with fₛ at the second terminal 478; perform filtering operations on the second samples; and provide the second digital output at the third terminal 479 responsive to the second samples, the filtering operations, and the sampling clock signal. In some examples, the second filter 474 is a digital filter implemented in, for example, an ASIC, a programmable logic circuit such as an FPGA, or as software instructions in a DSP.

In the sensing system 400B of FIG. 4B, the voltage sensing circuit 404B operates to: receive a first voltage at the first terminal 406; receive a second voltage at the second terminal 408; and provide a first output (e.g., a voltage measurement signal) responsive to the first voltage, the second voltage, the operations of the first amplifier 412B, and the operations of the first processing circuit 420B. More specifically, the first amplifier 412B operates to: receive the first voltage at the first terminal 414; receive the second voltage at the second terminal 416; and provide a first amplified signal at the third terminal 418 responsive to the difference between the first voltage and the second voltage. In the example of FIG. 4B, the first processing circuit 420B operates to: receive the first amplified signal; receive the oversampling clock signal; receive the sampling clock signal having a lower frequency than the oversampling clock signal; and provide the first output signal responsive to the first amplified signal, the oversampling clock signal; the sampling clock signal, the operations of the first filter 434, and the operations of the first ADC 428.

In the example of FIG. 4B, the first filter 434 operates to: receive a first amplified signal from the first amplifier 412B at the first terminal 436; perform filtering operations on the first amplified signal; and provide first filtered results at the third terminal 439 responsive to the first amplified signal and the filtering operations. Also, the first ADC 428 operates to: receive the first filtered results at the first terminal 430; receive the sampling clock signal with frequency fₛ at the second terminal 432; and provide first samples of the first filtered results at the third terminal 433 based on the sampling clock signal. In the example of FIG. 4B, the first filter 434 may be a digital filter that operates to: receive the first amplified signal at the first terminal 436; perform filtering operations on the first samples; and provide the first filtered results at the third terminal 439 responsive to the first amplified signal and the filtering operations. In some examples, the first filter 434 is a digital filter implemented in, for example, an ASIC, programmable logic circuit such as an FPGA, or as software instructions in a DSP.

In the example of FIG. 4B, the current sensing circuit 444B operates to: receive the first voltage at the first terminal 446; receive a third voltage at the second terminal 448; and provide a second output signal (e.g., a current measurement signal) responsive to the first voltage, the third voltage, the operations of the second amplifier 452B, and the operations of the second processing circuit 460B. More specifically, the second amplifier 452B operates to: receive the first voltage at the first terminal 454; receive the third voltage at the second terminal 456; and provide a second amplified signal at the third terminal 458 responsive to the difference between the first voltage and the third voltage. The second processing circuit 460B operates to: receive the second amplified signal; receive the oversampling clock signal; receive the sampling clock signal; and provide the second output signal responsive to the second amplified signal, the oversampling clock signal, the sampling clock signal, operations of the second filter 474, and operations of the second ADC 468.

In the example of FIG. 4B, the second filter 474 operates to: receive a second amplified signal from the second amplifier 452B at the first terminal 476; perform filtering operations on the second amplified signal; and provide second filtered results at the third terminal 479 responsive to the second amplified signal and the filtering operations. In the example of FIG. 4B, the second ADC 468 operates to: receive the second filtered results at the first terminal 470; receive the sampling clock signal with frequency fₛ at the second terminal 472; and provide second samples of the second filtered results at the third terminal 473 based on the sampling clock signal. In the example of FIG. 4B, the second filter 474 may be a digital filter that operates to: receive the second amplified signal at the first terminal 476; perform filtering operations on the second amplified signal; and provide the second filtered results at the third terminal 479 responsive to the second amplified signal and the filtering operations. In the example of FIG. 4B, the second filter 474 may be a digital filter implemented in, for example, an ASIC, programmable logic circuit such as an FPGA, or as software instructions in a DSP.

With the sensing system 400A of FIG. 4A, or the sensing system 400B in FIG. 4B, the effects of aliased PWM harmonics (due to application of the drive signal to the control terminal of the transistor M2) can be reduced. In some examples, a processing circuit (e.g., the first processing circuit 420A in FIG. 4A, the second processing circuit 460A in FIG. 4A, the first processing circuit 420B in FIG. 4B, or the second processing circuit 460B in FIG. 4B) uses oversampling within a sigma-delta ADC and downconversion within a digital filter to minimize the impact of the PWM harmonics. In some examples, the sigma-delta ADC is used for the sampling and digitization of the current and voltage signals, resulting in an efficient implementation of a high SNR ADC with a sampling frequency that is suitable for EIS or other measurements. In some examples, the first ADC 428 and the second ADC 468 are sigma-delta ADCs, each sigma-delta ADC having a sigma-delta modulator responsible for oversampling a respective analog signal at an oversampling frequency fₒₛ, which relaxes the anti-alias filter specification. The anti-alias filter operates to filter out unwanted frequency content around multiples of fₛ. In some examples, the anti-alias filter is a CIC filter. In some examples, the sigma-delta modulator performs noise shaping that reduces noise at low frequencies and increase noise at high frequencies. In some examples, each of the first filter 434 and the second filter 474 attenuate high frequency noise of a sigma-delta modulator and down samples the output from a high frequency, low resolution output to a low frequency, high accuracy output with minimal noise folding.

In some examples, the first filter 434 and the second filter 474 are implemented as CIC filters. The frequency response of each CIC filter is a sinc function, which is characterized by zeros at multiples of the sampling frequency fₛ. In some examples, each CIC filter is used to attenuate PWM harmonics by setting the PWM frequency f_{PWM} to be equal to a multiple of the sampling frequency fₛ. In such examples, the PWM harmonics are in close vicinity of the zeros of the CIC frequency response, which provides significant attenuation of PWM harmonics. The remaining PWM harmonics that fold after the CIC filter attenuation are insignificant compared to the sensing signal and does not impact the impedance error.

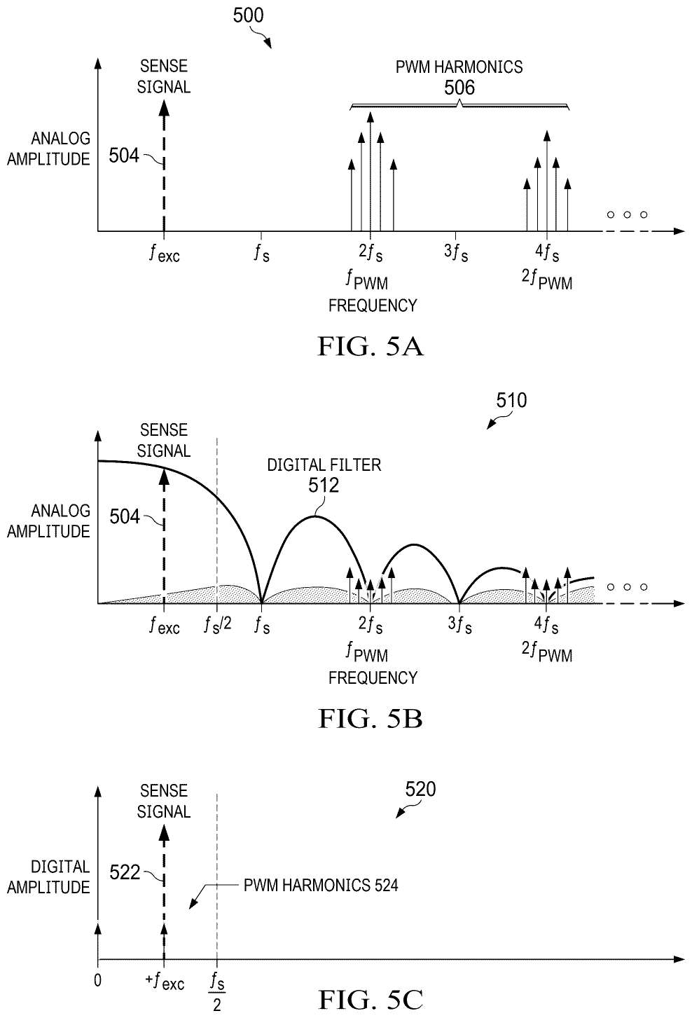

FIGS. 5A to 5C are diagrams 500, 510, and 520 showing the spectral behavior of an example sampling operation with PWM harmonics filtering performed by sensing system 400A in FIG. 4A, or the sensing system 400B in FIG. 4B. In the example of FIGS. 5A to 5C, the PWM frequency is twice the sampling frequency (i.e., f_{PWM}=2·fₛ). In the diagram 500 of FIG. 5A, an analog sense signal 504 at frequency f_{exc} and PWM harmonics 506 at frequencies f_{PWM} (e.g., 2fₛ) and 2f_{PWM} (e.g., 4fₛ) are represented. In the diagram 510 of FIG. 5B, a filter 512, such as filters 434 and 474 of FIGS. 4A and 4B, is applied, which results in some attenuation of the PWM harmonics 506. In some examples, the filter 512 includes zeros at fₛ and multiples of fₛ. In the diagram 520 of FIG. 5C, a digitized sense signal 522 and aliased PWM harmonics 524 are represented. In some examples, the digitized sense signal 522 and the aliased PWM harmonics 524 in the diagram 520 are the result of discrete Fourier transform operations applied to the filtered results of the diagram 510 in FIG. 5B. In the diagram 520, the aliased PWM harmonics 525 are at f_{alias_1}=−f_{exc}, f_{alias_2}=0, and f_{alias_3}=f_{exc} and are significantly reduced relative to the digitized sense signal 522 due to the digital filter 512.

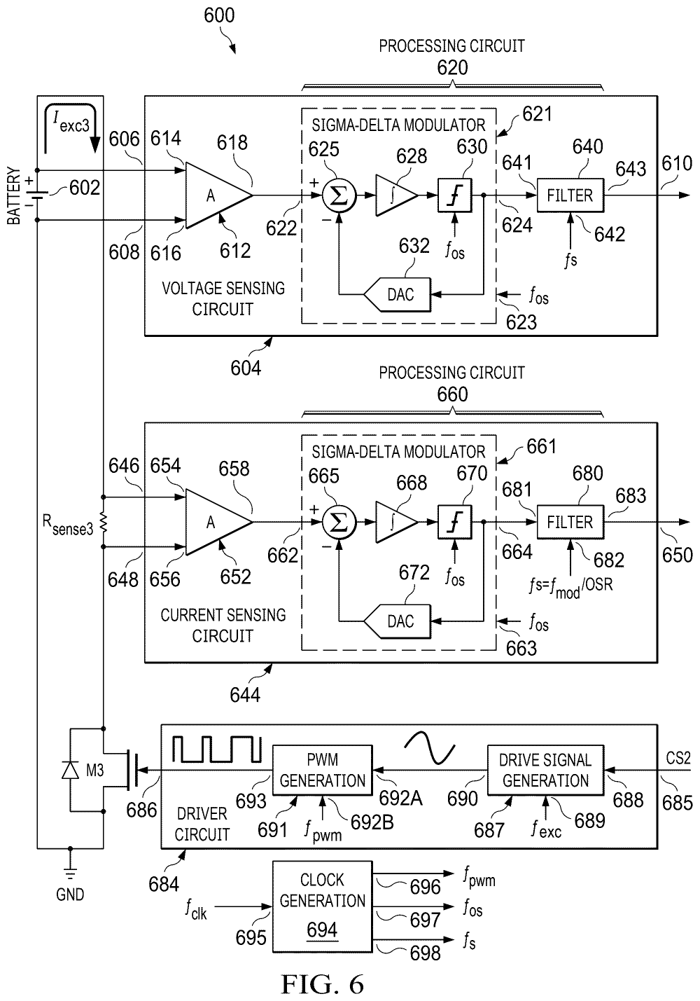

FIG. 6 is a diagram showing an example sensing system 600 with PWM harmonics filtering. In some examples, the sensing system 600 can be an example of sensing system 400A of FIG. 4A or the sensing system 400B of FIG. 4B. In the example of FIG. 6, the sensing system 600 is an EIS measurement scenario for a battery 602. In other examples, the battery 602 may be replaced by a motor or other electronic device. As shown, the sensing system 600 includes a sense resistor Rₛₑₙₛₑ₃, a transistor M3, a voltage sensing circuit 604, a current sensing circuit 644, a driver circuit 684, and clock generation circuitry 694. The sense resistor Rₛₑₙₛₑ₃, the transistor M3, the voltage sensing circuit 404, and the current sensing circuit 444 are example components of the sensing circuitry 108 in FIG. 1. The driver circuit 684 is an example of the driver circuit 122 in FIG. 1. The clock generation circuitry 694 is an example component of the control unit 116 in FIG. 1. In the example of FIG. 6, the clock generation circuitry 694 has a first terminal 695, a second terminal 696, a third terminal 697, and a fourth terminal 698.

As shown, the voltage sensing circuit 604 has a first terminal 606, a second terminal 608, and a third terminal 610. The voltage sensing circuit 604 includes a first amplifier 612 and a first processing circuit 620, which includes sampling and harmonics filtering circuitry. The first processing circuit 620 is an example of the sampling and harmonics filtering circuitry 115 in FIG. 1 and the first processing circuit 420A of FIG. 4A. In the example of FIG. 6, the first amplifier 612 has a first terminal 614, a second terminal 616, and a third terminal 618. The first processing circuit 620 includes a first sigma-delta modulator 621 and a first filter 640. The first sigma-delta modulator 621 can be an example of first ADC 428 of FIG. 4A, and the first filter 640 can be an example of first filter 434 of FIG. 4A. In the example of FIG. 6, the first sigma-delta modulator 621 includes a first difference generation block 625, a first integrator 628, a first quantizer 630, and a first digital-to-analog converter (DAC) 632 in the feedback arrangement shown. As shown, the first sigma-delta modulator 621 has a first terminal 622, a second terminal 623, and a third terminal 624. The first filter 640 has a first terminal 641, a second terminal 642, and a third terminal 643. The first terminal 606 of the voltage sensing circuit 604 is coupled to the first terminal of the battery 602. The second terminal 608 of the voltage sensing circuit 604 is coupled to a second terminal of the battery 602. The second terminal 608 of the voltage sensing circuit 604 is coupled to the second terminal of the battery 602. The third terminal 610 of the voltage sensing circuit 604 is coupled to a processing unit (e.g., the processing unit 128 in FIG. 1).

The first terminal 614 of the first amplifier 612 is coupled to the first terminal 606 of the voltage sensing circuit 604. The second terminal 616 of the first amplifier 612 is coupled to the second terminal 608 of the voltage sensing circuit 604. The third terminal 618 of the first amplifier 612 is coupled to the first terminal 622 of the first sigma-delta modulator 621. The second terminal 623 of the first sigma-delta modulator 621 is coupled to the third terminal 697 of the clock generation circuitry 694. The third terminal 624 of the first sigma-delta modulator 621 is coupled to the first terminal 641 of the first filter 640. The second terminal 642 of the first filter 640 is coupled to the fourth terminal 698 of the clock generation circuitry 694. The third terminal 643 of the first filter 640 is coupled to the third terminal 610 of the voltage sensing circuit 604.

In some examples, the first filter 640 can be coupled between third terminal 618 of first amplifier 612 and first terminal 622 of the first sigma-delta modulator 621, where the first filter 640 performs a filtering operation on the output of the first amplifier 612, and the first sigma-delta modulator 621 can sample the filtered output of the first amplifier 612. In some examples, a downsampler can be coupled between the third terminal 624 of the first sigma-delta modulator 621 and the third terminal 610 of the voltage sensing circuit 604. In such examples, the first filter 640 can be an example of the first filter 434 of FIG. 4B.

The current sensing circuit 644 has a first terminal 646, a second terminal 648, and a third terminal 650. The current sensing circuit 644 includes a second amplifier 652 and a second processing circuit 660, which includes sampling and harmonics filtering circuitry. The second processing circuit 660 is an example of the sampling and harmonics filtering circuitry 115 in FIG. 1, the second processing circuit 460A in FIG. 4A, and the second processing circuitry 460B in FIG. 4B. In the example of FIG. 6, the second amplifier 652 has a first terminal 654, a second terminal 656, and a third terminal 658. The second processing circuit 660 includes a second sigma-delta modulator 661 and a second filter 680. The second sigma-delta modulator 661 can be an example of the second ADC 468 of FIGS. 4A and 4B, and the second filter 680 can be an example of the second filter 474 of FIGS. 4A and 4B. In the example of FIG. 6, the second sigma-delta modulator 661 includes a second difference generation block 665, a second integrator 668, a second quantizer 670, and a second DAC 672 in the feedback arrangement shown. The second sigma-delta modulator 661 has a first terminal 662, a second terminal 663, and a third terminal 664. The second filter 680 has a first terminal 681, a second terminal 682, and a third terminal 683.

The first terminal 646 of the current sensing circuit 644 is coupled to the first terminal of the sense resistor Rₛₑₙₛₑ₃. The second terminal 648 of the current sensing circuit 644 is coupled to the second terminal of the sense resistor Rₛₑₙₛₑ₃. The third terminal 650 of the current sensing circuit 644 is coupled to a processing unit (e.g., the processing unit 128 in FIG. 1).

The first terminal 654 of the second amplifier 652 is coupled to the first terminal 646 of the current sensing circuit 644. The second terminal 656 of the second amplifier 652 is coupled to the second terminal 648 of the current sensing circuit 644. The third terminal 658 of the second amplifier 652 is coupled to the first terminal 662 of the second sigma-delta modulator 661. The second terminal 663 of the second sigma-delta modulator 661 is coupled to the third terminal 697 of the clock generation circuitry 694. The third terminal 664 of the second sigma-delta modulator 661 is coupled to the first terminal 681 of the second filter 680. The second terminal 682 of the second filter 680 is coupled to the fourth terminal 698 of the clock generation circuitry 694. The third terminal 683 of the second filter 680 is coupled to the third terminal 650 of the current sensing circuit 644.

In some examples, the second filter 680 can be coupled between third terminal 658 of second amplifier 652 and first terminal 662 of second sigma-delta modulator 661, where the second filter 680 performs a filtering operation on the output of the second amplifier 652, and the second sigma-delta modulator 661 can sample the filtered output of the second amplifier 652. In some examples, a downsampler can be coupled between the third terminal 664 of the second sigma-delta modulator 661 and the third terminal 650 of the current sensing circuit 644. In such examples, the second filter 680 can be an example of the second filter 474 of FIG. 4B.

The driver circuit 684 has a first terminal 685 and a second terminal 686. In the example of FIGS. 6A and 6B, the driver circuit 684 includes drive signal generation circuitry 687 and PWM generation circuitry 691. The drive signal generation circuitry 687 has a first terminal 688, a second terminal 689, and a third terminal 690. The PWM generation circuitry 691 has a first terminal 692A, a second terminal 692B, and a second terminal 693.

The first terminal 685 of the driver circuit 684 may be coupled to a control unit (e.g., the control unit 116 in FIG. 1) and the first terminal 688 of the drive signal generation circuitry 687. The second terminal 689 of the drive signal generation circuitry 687 receives a control signal with frequency f_{exc}. The third terminal 690 of the drive signal generation circuitry 687 is coupled to the first terminal 692A of the PWM generation circuitry 691. The second terminal 692B of the PWM generation circuitry 691 receives a control signal with frequency f_{pwm}. The second terminal 693 of the PWM generation circuitry 691 is coupled to the second terminal 686 of the driver circuit 684 and the control terminal of the transistor M3. In the example of FIGS. 6A and 6B, the first terminal of the battery 602 is coupled to the first terminal of the sense resistor Rₛₑₙₛₑ₃. The second terminal of the sense resistor Rₛₑₙₛₑ₃ is coupled to the first terminal of the transistor M3. The second terminal of the transistor M3 is coupled to ground and the second terminal of the battery 602.

The clock generation circuitry 694 operates to: receive a master clock signal at the first terminal 695, the master clock signal having a frequency f_{CLK}; provide a PWM clock signal at the second terminal 696 responsive to the master clock signal, the PWM clock signal having a PWM frequency f_{PWM}; provide an oversampling clock signal at the third terminal 697 responsive to the master clock signal, the oversampling clock signal having an oversampling frequency fₒₛ; and provide a sampling clock signal at the fourth terminal 698 responsive to the master clock signal, the sampling clock signal having a sampling frequency fₛ. In some examples, f_{CLK} may be 10 to 20 MHZ, f_{PWM} may be 100 KHZ to 1 MHZ, fₒₛ may be 1 Hz to 20 MHZ, and fₛ may be 100 mHz to 2 MHz.

The driver circuit 684 operates to: receive the control signal CS2 at the first terminal 685; and generate a drive signal at the second terminal 686 responsive to the control signal CS2, operations of the drive signal generation circuitry 687, and operations of the PWM generation circuitry 691. In the example of FIGS. 6A and 6B, the drive signal has a frequency f_{pwm}. More specifically, in some examples, the drive signal generation circuitry 687 operates to: receive the control signal CS2 at the first terminal 688; receive a control signal with frequency f_{exc} at the second terminal 689; and generate a sinusoidal signal at the third terminal 690 responsive to the control signal CS2 and the control signal with frequency f_{exc}. In some examples, CS2 may indicate the excitation frequency f_{exc} instead of a separate control signal. In some examples, the PWM generation circuitry 691 operates to: receive the sinusoidal signal at the first terminal 692A; receive a control signal with frequency f_{pwm} at the second terminal 692B; and generate the drive signal at the second terminal 693 responsive to the sinusoidal signal and the control signal with frequency f_{pwm}. The drive signal is used to control on/off intervals of the transistor M3. When the transistor M3 is turned on, a current I_{exc3} flows from the first terminal of the battery 602 to ground and sensing operations are performed by the voltage sensing circuit 604 and/or the current sensing circuit 644.

In some examples, the voltage sensing circuit 604 operates to: receive a first voltage at the first terminal 606; receive a second voltage at the second terminal 608; and provide a first output (e.g., a voltage measurement signal) responsive to the first voltage, the second voltage, the operations of the first amplifier 612, and the operations of the first processing circuit 620. More specifically, the first amplifier 612 operates to: receive the first voltage level at the first terminal 614; receive the second voltage level at the second terminal 616; and provide a first amplified signal at the third terminal 618 responsive to the difference between the first voltage and the second voltage. The first processing circuit 620 operates to: receive the first amplified signal; receive the oversampling clock signal; receive a sampling clock signal; and provide the first output responsive to the first amplified signal, the oversampling clock signal; the sampling clock signal, the operations of the first sigma-delta modulator 621, and the operations of the first filter 640.

In some examples, the first sigma-delta modulator 621 operates to: receive the first amplified signal at the first terminal 622; receive an oversampling clock signal at the second terminal 623; and provide first samples of the first amplified signal at the third terminal 624 based on the oversampling clock signal, operations of the first difference generation block 625, operations of the first integrator 628, operations of the first quantizer 630, and operations of the first DAC 632. In some examples, the first filter 640 operates to: receive the first samples at the first terminal 641; receive a sampling clock signal at the second terminal 642; perform filtering operations on the first samples; and provide the first output at the third terminal 643 responsive to the first samples, the filtering operations, and the sampling clock signal.

In some examples, the current sensing circuit 644 operates to: receive the first analog voltage level at the first terminal 646; receive a third analog voltage level at the second terminal 648; and provide a second output (e.g., a current measurement signal) responsive to the first voltage level, the third voltage level, the operations of the second amplifier 652, and the operations of the second processing circuit 660. More specifically, the second amplifier 652 operates to: receive the first voltage level at the first terminal 654; receive the third voltage level at the second terminal 656; and provide a second amplified signal at the third terminal 658 responsive to the difference between the first voltage level and the third voltage level. The second processing circuit 660 operates to: receive the second amplified signal; receive the oversampling clock signal; receive the sampling clock signal; and provide the second output responsive to the oversampling clock signal, the second amplified signal, the sampling clock signal, operations of the second sigma-delta modulator 661, and operations of the second filter 680.

In some examples, the second sigma-delta modulator 661 operates to: receive the second amplified signal at the first terminal 662; receive the oversampling clock signal at the second terminal 663; and provide second samples of the second amplified signal at the third terminal 664 based on the oversampling clock signal, operations of the second difference generation block 665, operations of the second integrator 668, operations of the second quantizer 670, and operations of the second DAC 672. In some examples, the second filter 680 operates to: receive the second samples at the first terminal 681; receive the sampling clock signal at the second terminal 682; perform filtering operations on the second samples; and provide the second digital output at the third terminal 683 responsive to the second samples, the filtering operations, and the sampling clock signal.

With the sensing system 600, the effects of aliased PWM harmonics (due to application of the drive signal to the control terminal of the transistor M3) are minimized without the need for a pre-ADC analog filter. In the example of FIG. 6, sampling and harmonics filtering circuitry (e.g., of the first processing circuit 620, or of the second processing circuit 660) uses oversampling with sigma-delta modulators, and filters to minimize the impact of the PWM harmonics. In some examples, the sigma-delta modulators perform oversampling and digitization of the current and voltage signals, resulting in an efficient implementation of a high SNR ADC with a sampling frequency that is suitable for EIS or other measurements. In some examples, each of the sigma-delta modulators are responsible for oversampling a respective analog signal at an oversampling frequency f_{mod}, which relaxes the anti-alias filter specification. The anti-alias filter operates to filter out unwanted frequency content around multiples of fₛ. In some examples, the anti-alias filter is a CIC filter. In some examples, each sigma-delta modulator performs noise shaping that reduces noise at low frequencies and increase noise at high frequencies. Each of the first filter 640 and the second filter 680 attenuates high frequency noise of a respective sigma-delta modulator and down sample the output from a high frequency, low resolution output to a low frequency, high accuracy output with minimal noise folding. In some examples, the first filter 640 and the second filter 680 are CIC filters.

In some examples, the amplifier output of the voltage sensing circuit 604 and/or the current sensing circuit 644 may be sampled by a sigma-delta ADC that includes a single-bit sigma-delta modulator followed by a digital filter. Each sigma-delta modulator may include an integrator (e.g., the first integrator 628 or the second integrator 668 in FIG. 6), a high-frequency quantizer operating at fₒₛ (e.g., the first quantizer 630 or the second quantizer 670 in FIG. 6) and a DAC (e.g., the first DAC 632 or the second DAC 672 in FIG. 6). The sigma-delta modulator is responsible of oversampling the signal by an oversampling ratio (OSR) which is equal to fₒₛ divided by the sampling frequency fₛ (i.e., OSR=fₒₛ/fₛ).

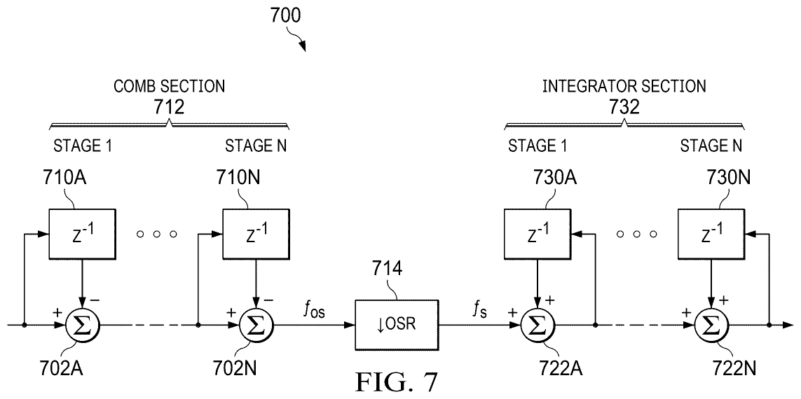

In some examples, each sigma-delta modulator is followed by a digital filter or preceded by an analog filter (e.g., the first filter 640 or the second filter 680 in FIGS. 6A and 6B) to attenuate the high frequency noise resulted from the sigma-delta modulation and the aliasing of the PWM harmonics. In some examples, the digital filter (or a standalone downsampler) may also downsample the modulator output at the oversampling frequency fₒₛ by the ratio OSR to a digital word at the lower sampling frequency fₛ. In some examples, each digital filter includes a comb section, downsampling by the OSR ratio, and then an integrator section as in FIG. 7. The comb and integrator sections include a number of differentiator stages and integrator stages, respectively. The number of stages in both sections are used to determine the order for the sinc function. A larger number of stages increases the order to the sinc function which increases the noise attenuation. The zeros of the sinc function occur at the frequencies n*fₛ, where n is an integer with values 1, 2, . . . , etc. The PWM frequency is adjusted to be a multiple of fₛ such that the PWM harmonics are aligned with the zeros of the sinc function of the CIC filter. In some examples, a clock generator is used to: derive the PWM clock signal with f_{PWM}; derive the oversampling clock signal with fₒₛ; and derive the sampling clock signal with fₛ from a master clock signal with f_{CLK}. In some examples, the master clock signal with frequency f_{CLK} is divided by a power of 2 to generate clocks signals with frequencies f_{PWM}, fₒₛ and fₛ such that f_{PWM}=k*fₛ and fₒₛ=OSR*fₛ, where k and OSR are integers.

FIG. 7 is a diagram showing an example filter 700 which can be part of the first filter 640 and/or the second filter 680 in FIG. 6. In the example of FIG. 7, the filter 700 is a digital CIC filter implemented with digital logic circuitry, which can be part of an ASIC, a FPGA, a DSP, etc. As shown, the filter 700 includes a comb section 712, a downsampler 714, and an integrator section 732. The comb section 712 includes delay elements 710A to 710N and difference generation blocks 702A to 702N in the arrangement shown. In the example of FIG. 7, the comb section 712 has N stages, where each stage include a respective delay element of the delay elements 710A to 710N and a respective difference generation block of the difference generation blocks 702A to 702N. The integrator section 732 includes delay elements 730A to 730N and summation blocks 722A to 722N in the arrangement shown. In the example of FIG. 7, the integrator section 732 has N stages, where each stage include a respective delay element of the delay elements 730A to 730N and a respective summation block of the summation blocks 722A to 722N. The filter 700 provides an efficient infinite impulse response (IIR) filter option for PWM harmonics filtering. In other examples, filter 700 may include a finite impulse response (FIR) filter, a Butterworth filter, or a Parks-McClellan filter.

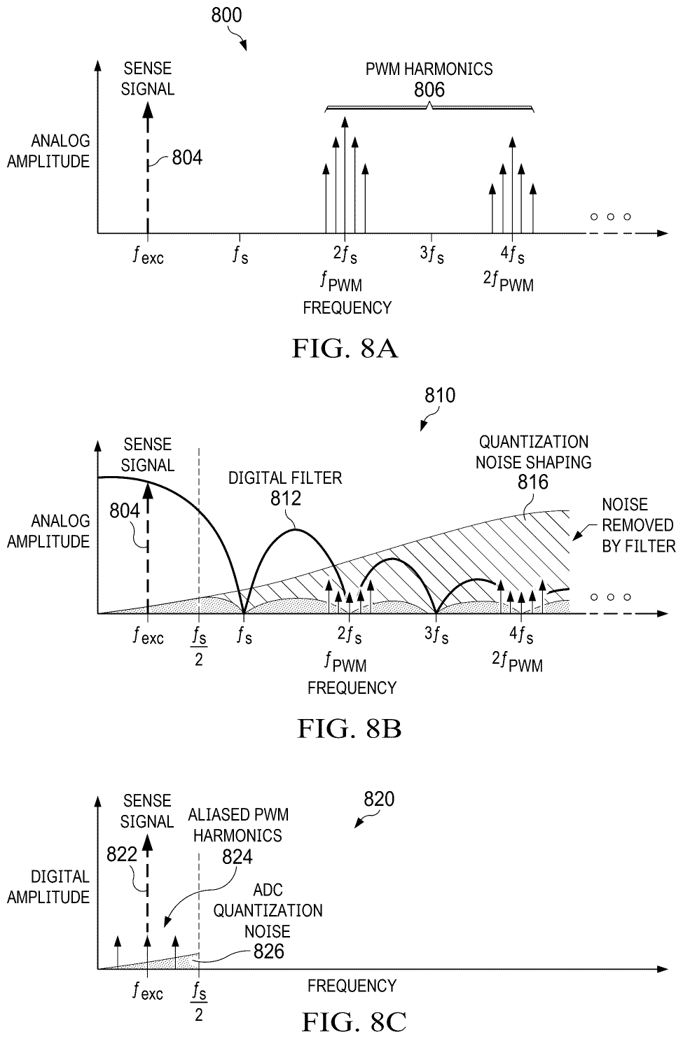

FIGS. 8A to 8C are diagrams 800, 810, and 820 showing the spectral behavior of an example sampling operation with PWM harmonics filtering provided by sensing system 600 with sigma-delta modulators. In the example of FIG. 8A to 8C, an oversampled CIC filter is used for PWM harmonics filtering and the PWM frequency is twice the sampling frequency (i.e., f_{PWM}=2·fₛ). In the diagram 800 of FIG. 8A, an analog sense signal 804 at frequency f_{exc} and PWM harmonics 806 at frequencies f_{PWM} (e.g., 2fₛ) and 2f_{PWM} (e.g., 4fₛ) are represented. In the diagram 810 of FIG. 8B, a digital filter 812 is applied, which results in some attenuation of the PWM harmonics 806. In some examples, the digital filter 812 includes zeros at fₛ and multiples of fₛ. In the diagram 820 of FIG. 8C, a digitized sense signal 822, aliased PWM harmonics 824, and ADC quantization noise 826 are represented. In some examples, the digitized sense signal 822, the digitized PWM harmonics 824, and the ADC quantization noise 826 in the diagram 820 are the result of discrete Fourier transform operations applied to the filtered results of the diagram 810 in FIG. 8B. In the diagram 820, the aliased PWM harmonics 825 are at f_{alias_1}=−f_{exc}, f_{alias_2}=0, and f_{alias_3}=f_{exc} and are significantly reduced relative to the digitized sense signal 822 due to the digital filter 812. In the examples, of FIG. 8C, the aliased PWM harmonics 824 are slightly greater than the ADC quantization noise 826 but does not significantly affect the SNR of the digitized sense signal 822.

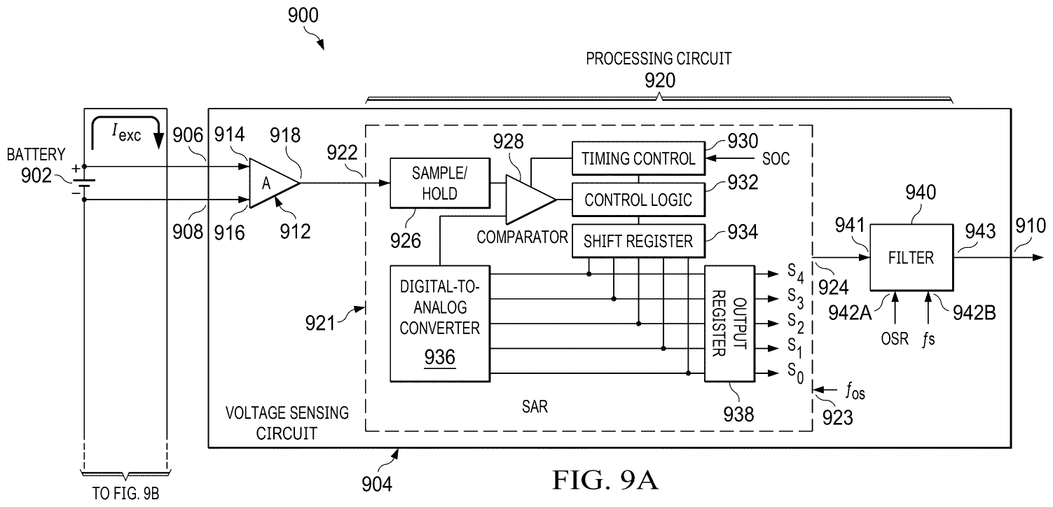

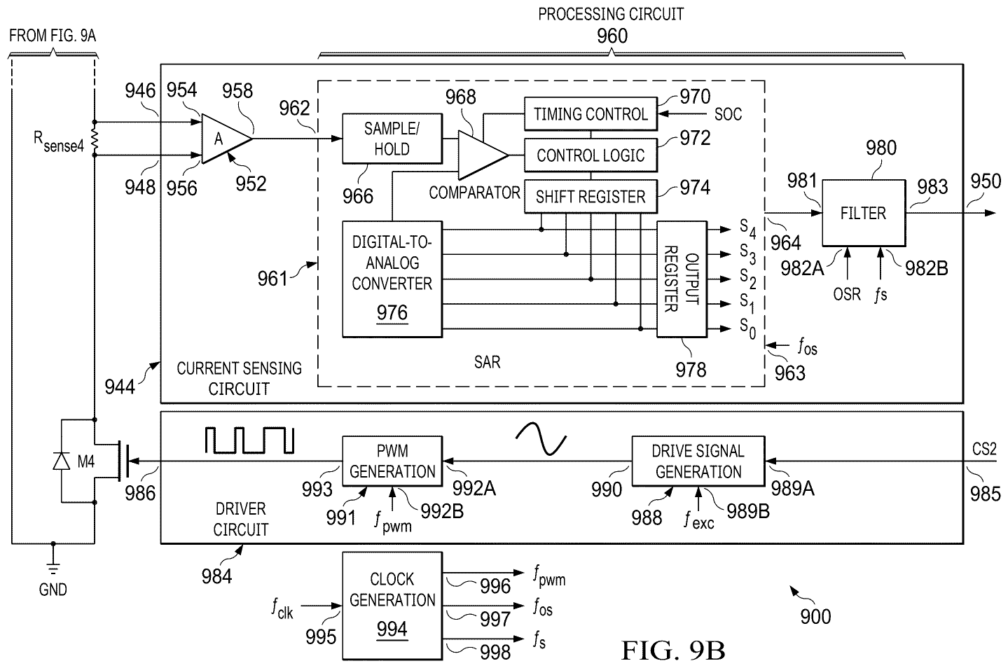

FIGS. 9A and 9B are schematic diagrams showing another example sensing system 900 with PWM harmonics filtering. The sensing system 900 can be an example of the sensing systems 400A of FIG. 4A, of the sensing system 400B of FIG. 4B. In the example of FIGS. 9A and 9B, the sensing system 900 is an EIS measurement scenario for a battery 902. In other examples, the battery 902 may be replaced by a motor or other electronic device. As shown, the sensing system 900 includes a sense resistor Rₛₑₙₛₑ₄, a transistor M4, a voltage sensing circuit 904, a current sensing circuit 944, a driver circuit 984, and clock generation circuitry 994. The sense resistor Rₛₑₙₛₑ₄, the transistor M4, the voltage sensing circuit 904, and the current sensing circuit 944 are example components of the sensing circuitry 108 in FIG. 1. The driver circuit 984 is an example of the driver circuit 122 in FIG. 1. The clock generation circuitry 994 is an example component of the control unit 116 in FIG. 1. In the example of FIG. 9, the clock generation circuitry 994 has a first terminal 995, a second terminal 996, a third terminal 997, and a fourth terminal 998.

As shown, the voltage sensing circuit 904 has a first terminal 906, a second terminal 908, and a third terminal 910. The voltage sensing circuit 604 includes a first amplifier 912 and a first processing circuit 920, which includes sampling and harmonics filtering circuitry. The first processing circuit 920 is an example of the sampling and harmonics filtering circuitry 115 in FIG. 1, the first processing circuit 420A of FIG. 4A, and the first processing circuit 420B of FIG. 4B. In the examples of FIGS. 9A and 9B, the first amplifier 912 has a first terminal 914, a second terminal 916, and a third terminal 918. The first processing circuit 920 includes a first successive-approximation (SAR) ADC 921 and a first filter 940, which can be an example of first filter 434 with zeros at n (one or more) times the sampling frequency fₛ and/or the PWM frequency f_{pwm}. The first SAR ADC 921 has a first terminal 922, a second terminal 923, and a third terminal 924. In some examples, the first SAR ADC 921 includes a first sample/hold circuit 926, a first comparator 928, a first timing circuit 930, first control logic 932, a first shift register 934, a first DAC 936, and a first output register 938 in the arrangement shown. The first filter 940 has a first terminal 941, a second terminal 942A, a third terminal 942B, and a fourth terminal 943. In some examples, the first terminal 941 of the first filter 940 can be coupled to the third terminal 924 of the first SAR ADC 921 and the fourth terminal 943 of the first filter 940 can be coupled to the third terminal 910 of the first processing circuit 920, as shown in FIG. 9A. In some examples, the first terminal 941 of the first filter 940 can be coupled to the first terminal 922 of the first SAR ADC 921, and the third terminal 924 of the first SAR ADC 921 can be coupled to the third terminal 910 of the first processing circuit 920, where the first filter 940 filters the output of the first amplifier 912, and the first SAR ADC 921 samples the filtered output of the first amplifier 912, followed by a downsampler to downsample the outputs of the first SAR ADC 921. The first filter 940 can be a digital filter or an analog filter with zeros at n (one or more) times the sampling frequency fₛ and/or the PWM frequency f_{pwm}, and can be an example of the first filter 434 in FIGS. 4A and 4B, or the first filter 640 in FIG. 6.

The first terminal 906 of the voltage sensing circuit 904 is coupled to the first terminal of the battery 902. The second terminal 908 of the voltage sensing circuit 904 is coupled to a second terminal of the battery 902. The second terminal 908 of the voltage sensing circuit 904 is coupled to the second terminal of the battery 902. The third terminal 910 of the voltage sensing circuit 904 is coupled to a processing unit (e.g., the processing unit 128 in FIG. 1).

The first terminal 914 of the first amplifier 912 is coupled to the first terminal 906 of the voltage sensing circuit 904. The second terminal 916 of the first amplifier 912 is coupled to the second terminal 908 of the voltage sensing circuit 904. The third terminal 918 of the first amplifier 912 is coupled to the first terminal 922 of the first SAR ADC 921. The second terminal 923 of the first SAR ADC 921 is coupled to the third terminal 997 of the clock generation circuitry 994. The third terminal 924 of the first SAR ADC 921 is coupled to the first terminal 941 of the first filter 940. The second terminal 942A of the first filter 940 receives an OSR value. In the example of FIG. 9A, the third terminal 942B of the first filter 940 is coupled to the fourth terminal 998 of the clock generation circuitry 994. The fourth terminal 943 of the first filter 940 is coupled to the third terminal 910 of the voltage sensing circuit 904.

The current sensing circuit 944 has a first terminal 946, a second terminal 948, and a third terminal 950. The current sensing circuit 944 includes a second amplifier 952 and a second processing circuit 960, which includes sampling and harmonics filtering circuitry. The second processing circuit 960 is an example of the sampling and harmonics filtering circuitry 115 in FIG. 1, and the second filter 474 in FIGS. 4A and 4B. In the example of FIG. 9B, the second amplifier 952 has a first terminal 954, a second terminal 956, and a third terminal 958. The second processing circuit 960 includes a second SAR ADC 961 and a second filter 980. The second SAR ADC 961 has a first terminal 962, a second terminal 963, and a third terminal 964. In some examples, the second SAR ADC 961 includes a second sample/hold circuit 966, a second comparator 968, a second timing circuit 970, second control logic 972, a second shift register 974, a second DAC 976, and a second output register 978 in the arrangement shown. The second filter 980, which can be an example of second filter 474 in FIGS. 4A and 4B, or the second filter 680 in FIG. 6 with zeros at n (one or more) times the sampling frequency fₛ and/or the PWM frequency f_{pwm}, has a first terminal 981, a second terminal 982A, and third terminal 982B, and a fourth terminal 983.

In some examples, the first terminal 981 of the second filter 980 can be coupled to the third terminal 964 of the second SAR ADC 961 and the fourth terminal 983 of the second filter 980 can be coupled to the third terminal 950 of the current sensing circuit 944, as shown in FIG. 9A. In some examples, the first terminal 981 of the second filter 980 can be coupled to the first terminal 962 of the second SAR ADC 961, and the third terminal 924 of the second SAR ADC 961 can be coupled to the third terminal 950 of the current sensing circuit 944, where the second filter 980 filters the output of the second amplifier 952, and the second SAR ADC 961 samples the filtered output of the second amplifier 952, followed by a downsampler to downsample the output of the second SAR ADC 961. The second filter 980 can be a digital filter or an analog filter with zeros at n (one or more) times the sampling frequency fₛ and/or the PWM frequency f_{pwm}, and can be an example of the second filter 474 in FIGS. 4A and 4B, or the second filter 680 in FIG. 6.

The first terminal 946 of the current sensing circuit 944 is coupled to the first terminal of the sense resistor Rₛₑₙₛₑ₄. The second terminal 948 of the current sensing circuit 944 is coupled to the second terminal of the sense resistor Rₛₑₙₛₑ₄. The third terminal 950 of the current sensing circuit 944 is coupled to a processing unit (e.g., the processing unit 128 in FIG. 1).

The first terminal 954 of the second amplifier 952 is coupled to the first terminal 946 of the current sensing circuit 944. The second terminal 956 of the second amplifier 952 is coupled to the second terminal 948 of the current sensing circuit 944. The third terminal 958 of the second amplifier 952 is coupled to the first terminal 962 of the second SAR ADC 961. The second terminal 963 of the second SAR ADC 961 is coupled to the third terminal 997 of the clock generation circuitry 994. The third terminal 964 of the second SAR ADC 961 is coupled to the first terminal 981 of the second filter 980. The second terminal 982A of the second filter 980 receives an OSR value. The third terminal 982B of the second filter 980 is coupled to the fourth terminal 998 of the clock generation circuitry 994. The fourth terminal 983 of the second filter 980 is coupled to the third terminal 950 of the current sensing circuit 944.

The driver circuit 984 has a first terminal 985 and a second terminal 986. In the example of FIG. 9, the driver circuit 984 includes drive signal generation circuitry 988 and PWM generation circuitry 991. The drive signal generation circuitry 988 has a first terminal 989A, a second terminal 989B, and a third terminal 990. The PWM generation circuitry 991 has a first terminal 992A, a second terminal 992B, and a third terminal 993.

The first terminal 985 of the driver circuit 984 may be coupled to a control unit (e.g., the control unit 116 in FIG. 1) and the first terminal 989A of the drive signal generation circuitry 988. The second terminal 989B of the drive signal generation circuitry 988 receives a control signal with frequency f_{exc}. The third terminal 990 of the drive signal generation circuitry 988 is coupled to the first terminal 992A of the PWM generation circuitry 991. The second terminal 992B of the PWM generation circuitry 991 receives a control signal with frequency f_{pwm}. The third terminal 993 of the PWM generation circuitry 991 is coupled to the second terminal 986 of the driver circuit 984 and the control terminal of the transistor M4. In the example of FIG. 9, the first terminal of the battery 902 is coupled to the first terminal of the sense resistor Rₛₑₙₛₑ₄. The second terminal of the sense resistor Rₛₑₙₛₑ₄ is coupled to the first terminal of the transistor M4. The second terminal of the transistor M4 is coupled to ground and the second terminal of the battery 902.

The clock generation circuitry 994 operates to: receive a master clock signal at the first terminal 995, the master clock signal having a frequency f_{CLK}; provide a PWM clock signal at the second terminal 996 responsive to the master clock signal, the PWM clock signal having a PWM frequency f_{PWM}; provide an oversampling clock signal at the third terminal 997 responsive to the master clock signal, the oversampling clock signal having an oversampling frequency fₒₛ; and provide a sampling clock signal at the fourth terminal 998 responsive to the master clock signal, the sampling clock signal having a sampling frequency fₛ. In some examples, f_{CLK} may be 10 to 20 MHZ, f_{PWM} may be 100 kHz to 1 MHZ_, fₒₛ may be 1 Hz to 20 MHZ, and fₛ may be 100 mHz to 2 MHz.

The driver circuit 984 operates to: receive the control signal CS2 at the first terminal 985; and generate a drive signal at the second terminal 986 responsive to the control signal CS2, operations of the drive signal generation circuitry 988, and operations of the PWM generation circuitry 991. In the example of FIG. 9, the drive signal has a frequency f_{pwm}. More specifically, in some examples, the drive signal generation circuitry 988 operates to: receive the control signal CS2 at the first terminal 989A; receive a control signal with frequency f_{exc} at the second terminal 989B; and generate a sinusoidal signal at the third terminal 990 responsive to the control signal CS2 and the control signal with frequency f_{exc}. In some examples, CS2 may provide an indication of the excitation frequency f_{exc} instead of another control signal. In some examples, the PWM generation circuitry 991 operates to: receive the sinusoidal signal at the first terminal 992A; receive a control signal with frequency f_{pwm} at the second terminal 992B; and generate the drive signal at the third terminal 993 responsive to the sinusoidal signal and the control signal with frequency f_{pwm}. The drive signal is used to control on/off intervals of the transistor M4. When the transistor M4 is turned on, a current I_{exc3} flows from the first terminal of the battery 902 to ground and sensing operations are performed by the voltage sensing circuit 904 and/or the current sensing circuit 944.

In some examples, the voltage sensing circuit 904 operates to: receive a first analog voltage level at the first terminal 906; receive a second analog voltage level at the second terminal 908; and provide a first digital output (e.g., a voltage measurement signal) responsive to the first voltage level, the second voltage level, the operations of the first amplifier 912, and the operations of the first processing circuit 920. More specifically, the first amplifier 912 operates to: receive the first voltage level at the first terminal 914; receive the second voltage level at the second terminal 916; and provide a first amplified signal at the third terminal 918 responsive to the difference between the first voltage level and the second voltage level. The first processing circuit 920 operates to: receive the first amplified signal; receive the oversampling clock signal; receive a sampling clock signal; and provide the first digital output responsive to the first amplified signal, the oversampling clock signal, the sampling clock signal, the operations of the first SAR ADC 921, and the operations of the first filter 940. In some examples, the first SAR ADC 921 operates to: receive the first amplified signal at the first terminal 922; receive an oversampling clock signal at the second terminal 923; and provide first samples of the first amplified signal at the third terminal 924 based on the oversampling clock signal, operations of the first sample/hold circuit 926, operations of the first comparator 928, operations of the first timing circuit 930, operations of the first control logic 932, operations of the first shift register 934, operations of the first DAC 936, and operations of the first output register 938. In some examples, the first filter 940 operates to: receive the first samples at the first terminal 941; receive an OSR value at the second terminal 942A; receive a sampling clock signal at the third terminal 942B; perform filtering operations on the first samples; and provide the first digital output at the fourth terminal 943 responsive to the first samples, the filtering operations, the OSR value, and the sampling clock signal.

In some examples, the current sensing circuit 944 operates to: receive the first analog voltage level at the first terminal 946; receive a third analog voltage level at the second terminal 948; and provide a second digital output (e.g., a current measurement signal) responsive to the first voltage level, the third voltage level, the operations of the second amplifier 952, and the operations of the second processing circuit 960. More specifically, the second amplifier 952 operates to: receive the first voltage level at the first terminal 954; receive the third voltage level at the second terminal 956; and provide a second amplified signal at the third terminal 958 responsive to the difference between the first voltage level and the third voltage level. The second processing circuit 960 operates to: receive the second amplified signal; receive the oversampling clock signal; receive the sampling clock signal; and provide the second digital output responsive to the second amplified signal, the oversampling clock signal, the sampling clock signal, operations of the second SAR ADC 961, and operations of the second filter 980. In some examples, the second SAR ADC 961 operates to: receive the second amplified signal at the first terminal 962; receive the oversampling clock signal at the second terminal 963; and provide second samples of the second amplified signal at the third terminal 964 based on the oversampling clock signal, operations of the second sample/hold circuit 966, operations of the second comparator 968, operations of the second timing circuit 970, operations of the second control logic 972, operations of the second shift register 974, operations of the second DAC 976, and operations of the second output register 978. In some examples, the second filter 980 operates to: receive the second samples at the first terminal 981; receive an OSR value at the second terminal 982A; receive the sampling clock signal at the third terminal 982B; perform filtering operations on the second samples; and provide the second digital output at the fourth terminal 983 responsive to the second samples, the filtering operations, the OSR value, and the sampling clock signal.

With the sensing system 900, the effects of aliased PWM harmonics (due to application of the drive signal to the control terminal of the transistor M4) are minimized without the need for a pre-ADC analog filter. In the example of FIG. 9, sampling and harmonics filtering circuit (e.g., of the first processing circuit 920 and/or of the second processing circuit 960) uses oversampling with SAR ADC and filters to minimize the impact of the PWM harmonics. In some examples, the SAR ADC perform oversampling and digitization of the current and voltage signals, resulting in an efficient implementation of a high SNR ADC with a sampling frequency that is suitable for EIS or other measurements. In some examples, each of the SAR ADCs are responsible for oversampling a respective analog signal at an oversampling frequency fₒₛ, which relaxes the anti-alias filter specification. The anti-alias filter operates to filter out unwanted frequency content around multiples of fₛ. In some examples, the anti-alias filter is a CIC filter. In some examples, each SAR ADC performs noise shaping that reduces noise at low frequencies and increase noise at high frequencies. Each of the first filter 940 and the second filter 980 attenuate high frequency noise of a respective SAR ADC and down samples the output from a high frequency to a low frequency, with minimal noise folding. In some examples, the first filter 940 and the second filter 980 are CIC filters.

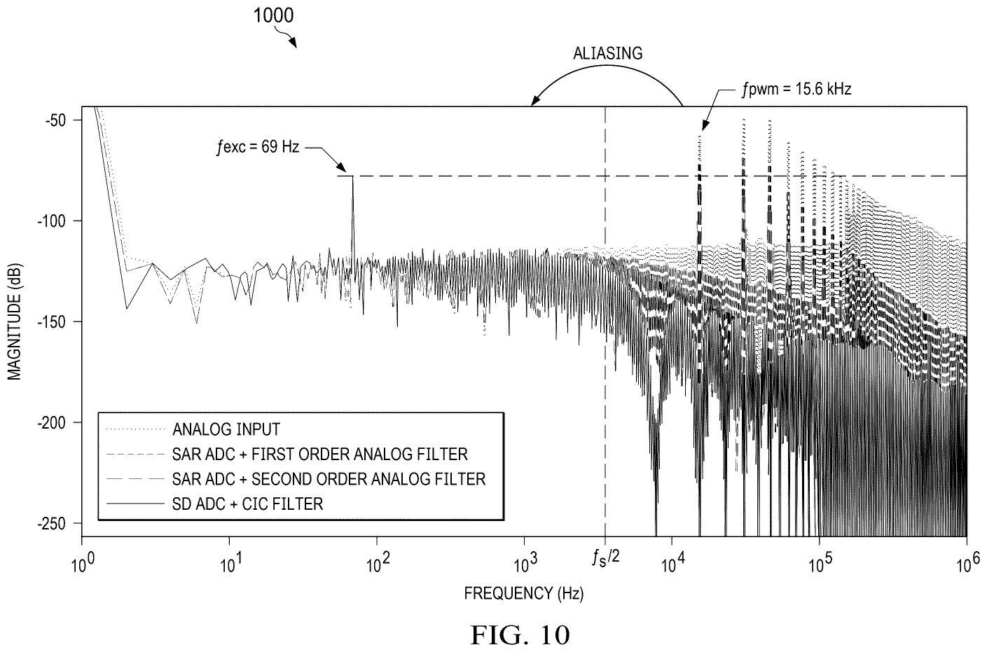

FIG. 10 is a graph 1000 showing frequency spectrums of outputs of sampling operations with different PWM harmonics filtering. In the graph 1000, the frequency response of an analog input, a SAR ADC with a 1^{st} order analog filter, a SAR ADC with a 2^{nd} order analog filter, and a sigma-delta ADC with a CIC filter are represented. For the graph 1000, f_{exc} is assumed to be 69 Hz, fₒₛ is assumed to be 2 MHZ, fₛ is assumed to be 7.8 Hz, the battery impedance is assumed to be 0.5 MΩ, the OSR is assumed to be 256, and f_{PWM} is assumed to be 2*fₛ. For the example of FIG. 10, the sigma-delta ADC filter may be based on a 1-bit quantizer running at a frequency of fₒₛ=2 MHz followed by a 3^{rd} order CIC filter.

With the sigma-delta ADC with a CIC filter example of FIG. 10, the impedance error (Zₑᵣᵣ) is approximately 0.8%. For a SAR ADC with a 1st order analog filter, the Zₑᵣᵣ is approximately 120%. For a SAR ADC with a 2nd order analog filter, the Zₑᵣᵣ is approximately 44%. As a result, in some examples, the PWM harmonics filtering method may use a sigma-delta ADC with a CIC filter due to its improved attenuation of PWM harmonics relative to a SAR ADC with a 1^{st} order analog filter and a SAR ADC with a 2^{nd} order analog filter.

In some examples, PWM harmonics filtering using a sigma-delta ADC with a CIC filter or other filter may provide the benefits of: attenuation of all PWM harmonics so that the PWM harmonics are insignificant compared to the sensing signal; low-cost implementation by properly designing the OSR factor and the PWM frequency with respect to the sampling frequency; reduced cost as there is no dedicated analog filter; low-cost PWM generation can be used without limitation on the level of the harmonics. In some examples, PWM harmonics filtering eliminates the impact of PWM harmonics on the entire frequency range of the excitation signal without the need for choosing specific excitation frequencies to avoid PWM harmonics aliasing.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. An apparatus comprising:
a driver circuit having a driver output, the driver circuit including a pulse width modulation (PWM) circuit configured to provide a PWM signal at the driver output at a frequency;
a sensing circuit having a sense input and a sense output; and
a processing circuit having a processing input and a processing output, the processing input coupled to the sense output, the processing circuit including a filter having zeros at the frequency and multiples of the frequency.

2. The apparatus of claim 1, wherein the frequency is a first frequency, and the apparatus further comprises a sampling circuit coupled between the sensing circuit and the processing circuit, the sampling circuit configured to provide samples at a second frequency.

3. The apparatus of claim 2, wherein the first frequency is an integer multiple of the second frequency.

4. The apparatus of claim 2, wherein the filter includes a comb section and an integrator section, the comb section configured to operate at a third frequency, and the integrator section configured to operate at the second frequency.

5. The apparatus of claim 2, wherein the filter implements a sinc function.

6. The apparatus of claim 4, wherein the sampling circuit includes a sigma-delta analog to digital converter (ADC) having a quantizer configured to provide the samples at the third frequency, the third frequency being related to the second frequency by an oversampling ratio.

7. The apparatus of claim 2, wherein the sampling circuit includes a successive approximation ADC.

8. The apparatus of claim 1, wherein the sense input is coupled to a battery terminal or a motor terminal.

9. The apparatus of claim 1, wherein the filter is an analog filter.

10. The apparatus of claim 1, wherein the filter is a digital filter.

11. A system comprising:
a device;
a sampling circuit having a sampling input, a sampling output, and a control terminal, the sampling input coupled to the device;
a driver circuit having a driver output coupled to the control terminal of the sampling circuit, the driver circuit including a pulse width modulation (PWM) circuit configured to provide a PWM signal at the driver output at a frequency;
a sensing circuit having a sense input and a sense output, the sense input coupled to the sampling output; and
a processing circuit having a processing input and a processing output, the processing input coupled to the sense output, the processing circuit including a filter having zeros at the frequency and multiples of the frequency.

12. The system of claim 11, wherein the device Includes a battery or a motor.

13. The system of claim 11, wherein the frequency is a first frequency, and the sampling circuit is configured to provide samples at a second frequency, and the filter is configured to provide a filtered version of the samples at the second frequency.

14. The system of claim 13, wherein the first frequency is an integer multiple of the second frequency.

15. The system of claim 13, wherein the filter includes at least one of an analog filter or a digital filter.

16. The system of claim 13, wherein the filter includes a comb section with a downconverter and an integrator section, the comb section configured to operate at a third frequency, and the integrator section configured to operate at the second frequency.

17. The system of claim 16, wherein the sampling circuit includes a sigma-delta analog to digital converter (ADC) having a quantizer configured to provide the samples at the third frequency, the third frequency being related to the second frequency by an oversampling ratio.

18. The system of claim 11, wherein the sampling circuit includes a successive approximation register (SAR) ADC.

19. A circuit comprising:
a first terminal;
a second terminal;
a switch between the first and second terminals of the circuit, the switch having a control terminal;
a driver circuit having a driver output coupled to the control terminal of the switch, the driver circuit including a pulse width modulation (PWM) circuit configured to provide a PWM signal at the driver output at a frequency; and
a voltage sensing circuit having a first terminal, a second terminal, and a third terminal, the first terminal of the voltage sensing circuit coupled to the first terminal of the circuit, and the second terminal of the voltage sensing circuit coupled to the second terminal of the circuit, the voltage sensing circuit including an analog-to-digital converter (ADC) and a filter having zeros at the frequency and multiples of the frequency.

20. The circuit of claim 19 comprising:
a third terminal; and
a current sensing circuit having a first terminal, a second terminal, and a third terminal, wherein the switch is between the second and third terminals of the circuit, the first terminal of the current sensing circuit is coupled to the first terminal of the circuit, the second terminal of the current sensing circuit is coupled to the third terminal of the circuit, and the current sensing circuit including an ADC and a filter having zeros at the frequency and multiples of the frequency.
